(19) United States
(12) Patent Application Publication
(10) Pub. No.: US 2024/0037304 A1
(43) Pub. Date: Feb. 1, 2024

(54) QUANTUM CIRCUIT FOR SIMULATING BOUNDARY OPERATOR

(71) Applicants: International Business Machines Corporation, Armonk, NY (US); University of the Witwatersrand, Braamfontein (ZA)

(72) Inventors: Ismail Yunus Akhalwaya, Emmarentia (ZA); Yang-Hui He, Oxford (GB); Lior Horesh, North Salem, NY (US); Vishnumohan Jejjala, Killarney (ZA); William Kirby, Cambridge, MA (US); Kugendran Naidoo, Midrand (ZA); Shashanka Ubaru, Ossining, NY (US)

(21) Appl. No.: 17/863,500

(22) Filed: Jul. 13, 2022

(51) Int. Cl. G06F 30/3308; G06N 10/20

(52) U.S. Cl. CPC G06F 30/3308; G06N 10/20

(57) ABSTRACT

An apparatus can include at least a controller, quantum hardware, and an interface. The controller can be configured to generate command signals. The quantum hardware can include at least a plurality of qubits. The interface can be connected to the controller and the quantum hardware, the interface being configured to control the quantum hardware based on the command signals to implement a quantum circuit configured to simulate a boundary operator that creates a mapping of boundaries of a given graph having nodes and edges. For example, the quantum circuit can be configured to simulate a boundary operator that creates a mapping of simplices of orders, e.g., of all orders, in a given simplicial complex. A method can include creating a boundary operator on a quantum computer, where a quantum circuit is built using Pauli spin operators.

The following disclosure(s) are submitted under 35 U.S.C. 102(b)(1)(A):
DISCLOSURE(S): Quantum Computing Algorithms for Decision Making under Uncertainty, Lior Horesh, Ken Clarkson, Vasileios Kalantzis, Mark Squillante, Shashanka Ubaru, Amir Abboud, July 2021;
Quantum Topological Data Analysis with Linear Depth and Exponential Speedup, Shashanka Ubaru, Ismail Yunus Akhalwaya, Mark S. Squillante, Kenneth L. Clarkson, Lior Horesh, arXiv:2108.02811v1, Aug. 5, 2021;
Don't Count the Shots, Make the Shots Count: Efficient Quantum Computation of the Fermionic Boundary Operator, Ismail Yunus Akhalwaya, Yang-Hui He, Lior Horesh, Vishnu Jejjala, William Kirby, Kugendran Naidoo, Shashanka Ubaru, arXiv:2201.11510v1, Jan. 27, 2022.

### BACKGROUND

The present application relates generally to computers and computer applications, and more particularly to quantum computing and quantum circuit that can perform boundary mapping on graphs (e.g., nodes and edges), for example, for facilitating analytics such as but not limited to topological data analysis and analysis of physical behavior of objects.

Classical computers use transistors to encode information in binary data, such as bits, where each bit can represent a value of 1 or 0. These 1s and 0s act as on/off switches that drive classical computer functions. If there are N bits of data, then there are 2^{A}N possible classical states, and one state is represented at a time.

Quantum computers uses quantum processors that operate on data represented by quantum bits, also known as qubits. One qubit can represent the classical binary states ‘0’, ‘1’, and also additional states that are superstitions of ‘0’ and ‘1’. Due to the ability to represent superpositions of ‘0’ and ‘1’, a qubit can represent both ‘0’ and ‘1’ states at the same time. For example, if there are N bits of data, then 2\hat{ }N quantum states can be represented at the same time. Further, qubits in a superposition can be correlated with each other, referred to as entanglement, where the state of one qubit (whether it is a 1 or a 0 or both) can depend on the state of another qubit, and more information can be encoded within the two entangled qubits. Based on superposition and entanglement principles, qubits can enable quantum computers to perform functions that may be relatively complex and time consuming for classical computers.

### BRIEF SUMMARY

The summary of the disclosure is given to aid understanding of a computing system and method of quantum circuit and generating a boundary operator, which can be used in quantum homology, for example, for big data analysis, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

An apparatus, in an aspect, can include a controller configured to generate command signals. The apparatus can also include quantum hardware including at least a plurality of qubits. The apparatus can further include an interface connected to the controller and the quantum hardware. The interface can be configured to control the quantum hardware based on the command signals to implement a quantum circuit, where the quantum circuit is configured to simulate a boundary operator that creates a mapping of boundaries of a given graph having at least nodes and edges. In an aspect, the quantum circuit has linear depth relative to number of nodes in the given graph.

A method, in an aspect, can include generating, by a controller of a quantum system, command signals. The method can also include converting, by an interface of the quantum system, the command signals into quantum operations. The method can further include, based on the quantum operations, controlling, by the interface of the quantum system, quantum hardware of the quantum system to construct a quantum circuit including at least Pauli quantum gates, the quantum circuit configured to simulate a boundary operator that creates a mapping of boundaries of a given graph having at least nodes and edges, where the quantum circuit has linear depth relative to number of nodes in the given graph.

A system, in an aspect, can include a first computing device configured to process data encoded in binary bits. The system can also include a second computing device configured to be in communication with the first computing device, the second computing device including at least a controller configured to generate command signals, quantum hardware including at least a plurality of qubits, and an interface connected to the controller and the quantum hardware. The interface can be configured to control the quantum hardware based on the command signals to implement a quantum circuit configured to simulate a boundary operator that creates a mapping of boundaries of a given graph having at least nodes and edges. In an aspect, the quantum circuit can have linear depth relative to the number of nodes in the given graph.

In another aspect, an apparatus can include a controller configured to generate command signals. The apparatus can also include quantum hardware including at least a plurality of qubits. The apparatus can further include an interface connected to the controller and the quantum hardware. The interface can be configured to control the quantum hardware based on the command signals to implement a quantum circuit configured to simulate a boundary operator that creates a mapping of simplices of orders in a given simplicial complex. The quantum circuit can have linear depth relative to the number of vertices in the given simplicial complex. The number of quantum gates in the quantum circuit can be linearly related to the number of vertices in the given simplicial complex.

A computer readable storage medium storing a program of instructions executable by a machine to perform one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a block diagram illustrating an example computing environment that can facilitate simulation of boundary operators in an embodiment.

FIG. 2 illustrates a quantum circuit that can simulate a boundary operator, e.g., given a simplicial complex with n number of vertices, where n is 4.

FIG. 3 illustrates an optimized version of the quantum circuit shown in FIG. 2 in an embodiment, where a series of gates is combined to obtain a simpler unitary gate.

FIG. 4 illustrates a quantum circuit that can simulate a boundary operator, e.g., given a simplicial complex with n number of vertices, where n is 8.

FIG. 5 illustrates an optimized version of the quantum circuit shown in FIG. 4 in an embodiment, where a series of gates is combined to obtain a simpler unitary gate.

FIG. 6 illustrates another example of an optimized quantum circuit that can simulate a boundary operator in an embodiment.

FIG. 7 illustrates an example of a quantum circuit that can simulate a boundary operator, which can be further optimized as shown in FIG. 6, in an embodiment.

FIG. 8A is a flow diagram illustrating a method of providing a quantum circuit that can simulate a boundary operator in an embodiment.

FIG. 8B is another flow diagram illustrating a method of providing a quantum circuit that can simulate a boundary operator in an embodiment.

FIG. 9 is a flow diagram illustrating a method of constructing a quantum circuit, which can simulate a boundary operator.

FIG. 10 illustrates a schematic of an example computer or processing system that may implement a quantum circuit, which can simulate a boundary operator in one embodiment.

FIG. 11 illustrates a schematic of an example quantum computing system that may implement a quantum circuit, which can simulate a boundary operator in one embodiment.

FIG. 12 illustrates a block diagram of an example system that can facilitate execution of a quantum algorithm in one embodiment.

FIG. 13 illustrates a cloud computing environment in one embodiment.

FIG. 14 illustrates a set of functional abstraction layers provided by cloud computing environment in one embodiment.

### DETAILED DESCRIPTION

Quantum computers are capable of performing linear algebraic operations in exponentially large spaces, and promise to achieve significant asymptotic speed-ups over classical computers. Big data refers to a collection of data that can be huge in size and further can grow, for example, exponentially. Extracting useful information from large data sets can be a difficult task. Topological methods for analyzing data sets provide a powerful technique for extracting such information. Persistent homology is a useful technique that can analyze the data and extract such topological features—connected components, holes, or voids—and, for example, determine how such features persist as the data is viewed at different scales. While a homology technique can find clusters, loops and voids in large datasets, and thus can find interesting features in big data, a classical computer implementing such a tool can encounter many challenges, including, for example, problem solution scaling and operation times. Quantum computing can speed up the process.

In one or more embodiments, systems, methods, apparatus and/or techniques can be provided, which can develop algorithms that may achieve quantum advantage for useful tasks, on quantum computers, including, for example but not limited to, noisy intermediate-scale quantum (NISQ) devices. More specifically, in one or more embodiments, one or more quantum circuits can be provided for performing a quantum computation task related to a boundary operator, used in various applications, including but not limited to, topological data analysis (TDA), machine learning, physical processes, and/or others. While the description refers to simplices and simplicial complex by way of example, one or more quantum circuits simulating the boundary operator can map generally the boundaries of a given graph, the graph having at least nodes and edges. For example, a grid can be made up of simplices. For example, a given graph can represent a simplicial complex, where polytopes formed by hyperedges of the graph can represent simplices in the simplicial complex, where for example, the boundary operator can create a mapping of simplices of all orders in the simplicial complex. The boundary operator can thus act on data such as, but not limited to, structured data points such as simplices, in a graph of nodes of edges, such as grid, mesh, manifold, simplicial complex of points and simplices.

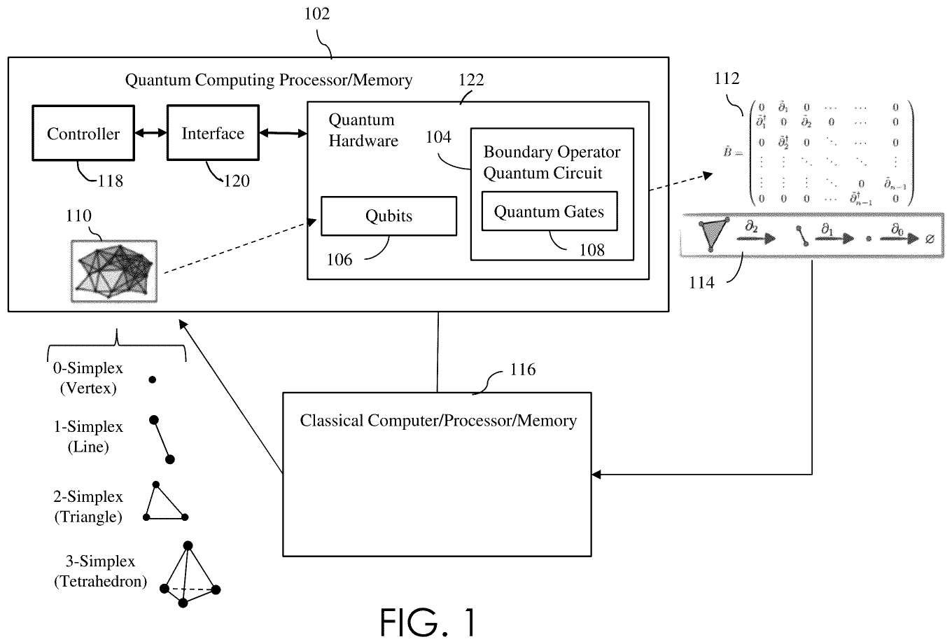

FIG. 1 is a block diagram illustrating an example computing environment that can facilitate simulation of one or more boundary operators in an embodiment. A quantum computing processor 102 can include or can construct one or more quantum circuits for performing quantum computations, for example, by applying various quantum gates 108 or operations on one or more qubits 106 or qubit states to result in quantum states of the qubits. For example, a quantum circuit can include a sequence of quantum gates and other operations, with initialization of qubits to some known values. A quantum circuit may also include one or more measurement components. In the following description, the input data is described as vertices of simplicial complex. However, it should be understood that techniques described herein, for example, quantum circuit and methods thereof, can be applicable to other graphs that include vertices (also referred to as nodes) and edges that may connect the vertices. For instance, another example of such a graph can be a mesh.

Referring to FIG. 1, quantum circuit 104 in one or more embodiments can simulate a boundary operator, e.g., constructs a boundary matrix 112 given n vertices of a simplicial complex (a collection of one or more simplices) 110. For example, the quantum circuit 104, which includes a sequence of operations of quantum gates 108 on qubits 106, can be configured to simulate a boundary operator that creates a mapping of orders of simplices in a given simplicial complex. The 2ⁿ (2\hat{ }n) possible simplices of the simplicial complex 110 can be mapped onto an n-qubit quantum state. Each vertex can be assigned a qubit 106 that is operated on by the quantum circuit 104. A simplicial complex 110 can be constructed based on distances between the vertices, for example, depending on the grouping scale E. For example, a simplicial complex can be constructed based on inclusion depending on the distance, which can be specified. This quantum state can contain exponentially fewer qubits than the number of bits required to describe the classical filtration of the complex. Given a simplicial complex, a boundary operator simulated by the quantum circuit 104 can create a mapping of orders of simplices (e.g., a boundary matrix 112). As explained below, the quantum circuit 104 can have linear depth relative to the number of vertices in the given simplicial complex (e.g., O(n)). Also as explained below, the number of quantum gates in the quantum circuit 104 can have a linear relationship with the number of vertices in the given simplicial complex (e.g., O(n)).

The input to the quantum circuit 104 can be a superposition over simplices, a quantum state that is a superposition of all simplices in the given data or given simplicial complex. For example, for a square (n=4, where n is the number of vertices), the input can be a superposition of four vertices (the four ‘1’ state (|0001>, |0010>, |0100>, |1000>) and four edges (|1100>, |0110>, |0011>, |1001>). So, in this example, the input can be a superposition of these 8 states. The output of the quantum circuit 104 can be quantum states of qubits representative of boundary matrix 112 applied to simplicial complex. Generally, a boundary matrix 112 sends a simplex 110 to a combination of its faces 112. That is, the boundary operator maps the vector space of k-simplices into the vector space of k−1 simplices. The quantum circuit 104 simulating the boundary operator calculates the boundary simplices, both “up” and “down”. For example, if the starting simplex is a triangle simplex, “down” would produce the edges of the triangle, “up” would produce the tetrahedron that the input triangle is a face of. To be described further below, the quantum circuit 104 implements quantum primitives or gates that map to Pauli operators or matrices. For example, the boundary operator can be represented in terms of Pauli spin operators, as a sum of Pauli spin operators, and the Pauli spin operators can be mapped into fermionic creation and annihilation operators.

In the example shown in FIG. 1, quantum computing processor 102 can be any suitable set of components capable of performing quantum operations on a physical system. A quantum operation can be, for example, a quantum gate operation that manipulate qubits to interact with one another in accordance with the quantum gate operation. In the example embodiment depicted in FIG. 1, quantum computing processor 102 can include a controller 118, an interface 120, and quantum hardware 122. In some embodiments, all or part of each of controller 118, interface 120, and quantum hardware 122 can be located in a cryogenic environment to aid in the performance of the quantum operations. Quantum hardware 122 may be any hardware capable of using quantum states to process information. Such hardware may include a plurality of qubits 106, and mechanisms to couple/entangle qubits 106, in order to process information using the quantum states. A qubit can be implemented as a physical device. Examples of physical implementation of a qubit can include, but not limited to, a superconducting qubit, a trapped ion qubit, and/or others. Qubits 106 may include, but are not limited to, charge qubits, flux qubits, phase qubits, spin qubits, and trapped ion qubits. Quantum hardware 122 can include a set of quantum gates 108, where quantum gates 108 can be configured to perform quantum logic operations on qubits 106. Quantum gates 108 can include one or more single-qubit gates, two-qubit gates, and/or other multi-qubit gates.

Controller 118 can be any combination of digital computing devices capable of performing a quantum computation, such as executing a quantum circuit 104, in combination with interface 120. Such digital computing devices may include digital processors and memory for storing and executing quantum commands using interface 120. Additionally, such digital computing devices may include devices having communication protocols for receiving such commands and sending results of the performed quantum computations to classical computer 116. Additionally, the digital computing devices may include communications interfaces with interface 120. In one embodiment, controller 118 can be configured to receive classical instructions (e.g., from classical computer 116) and convert the classical instructions into commands (e.g., command signals) for interface 120.

Interface 120 can be a classical-quantum interface including a combination of devices capable of receiving commands from controller 118 and converting the commands into quantum operations for implementing quantum hardware 122. In one embodiment, interface 120 can convert the commands from controller 118 into drive signals that can drive or manipulate qubits 106, and/or apply quantum gates 108 on qubits 106. Additionally, interface 120 can be configured to convert signals received from quantum hardware 122 into digital signals capable of processing and transmitting by controller 118 (e.g., to classical computer 116). Devices included in interface 120 can include, but are not limited to, digital-to-analog converters, analog-to-digital converters, waveform generators, attenuators, amplifiers, optical fibers, lasers, and filters.

Interface 120 can further include circuit components configured to measure a basis of the plurality of qubits following the implementation of quantum gates 108, where the measurement that will yield a classical bit result. For example, a basis of |0) corresponds to classical bit zero, and a basis of |1) corresponds to classical bit one. Each measurement performed by interface 120 can be read out to a device, such as classical computer 116, connected to quantum computing processor 102. A plurality of measurement results provided by interface 120 can result in a probabilistic outcome. In an embodiment, the qubit states output by quantum circuit 104 that simulates a boundary operator need not be measured, but can used directly by another quantum circuit, or used as input directly to another quantum circuit implemented on the quantum hardware 122.

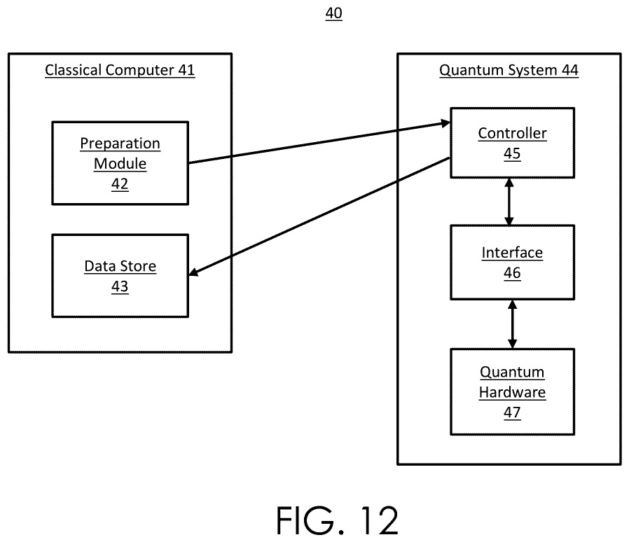

In an embodiment, quantum computing processor 102 may be quantum system 44 shown and described with reference to FIG. 12. Controller 118 may be controller 45 shown and described with reference to FIG. 12. Interface 120 may be interface 46 shown and described with reference to FIG. 12. Quantum hardware 122 may be quantum hardware 47 shown and described with reference to FIG. 12. The computing environment can also include other devices such an input device, which may set states of qubits in the quantum computing processor 102, and other devices and components for the quantum computing processor to function, such as but not limited to, buses and/or other interfaces.

Non-limiting examples of quantum gates 108, implemented on the quantum circuit 104 (e.g., using devices) can include Hadamard (or H) gates, controlled gates, and phase gates. The Hadamard gate acts on a single qubit and maps the basis state |0> to (|0>+|1>)/\sqrt{2} and the basis state |1> to (|0>−|1>)/\sqrt{2}. A phase gate acts on a single qubit and may alter the phase of one basis state of the qubit while leaving the other basis state unchanged. A controlled gate may act on two or more qubits, where one or more of the qubits provide a control for an operation.

The quantum computing processor 102 may also be connected to a classical computing processor 116 (e.g., a non-quantum computing device), which can interface with the quantum computing processor 102 and perform various pre-processing and/or post-processing tasks associated with the quantum computing performed on the quantum computing processor 102.

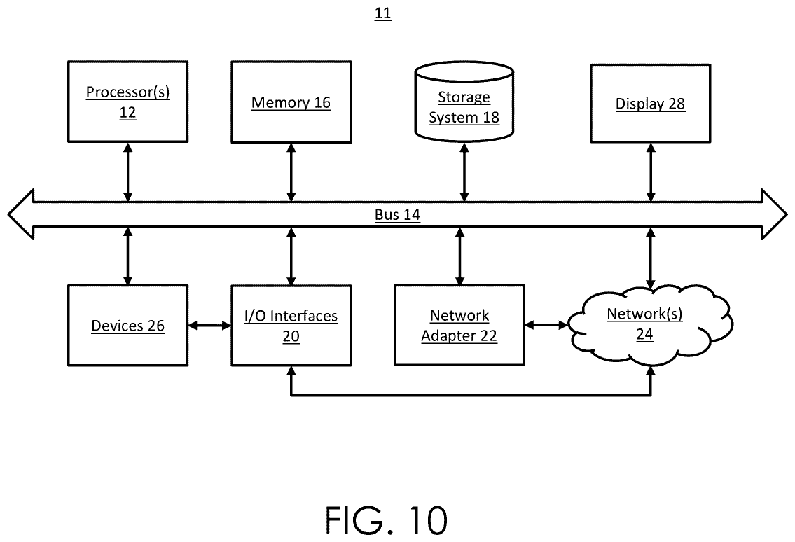

By example of post-processing, the classical computing processor 116 may perform scaling by a constant to obtain the boundary matrix 112. Classical computing processor 116 can include hardware components such as processors and storage devices (e.g., including memory devices and classical registers) for processing data encoded in classical bits. In one embodiment, classical computing processor 116 can be configured to control quantum computing processor 102 by providing various control signals, commands, and data encoded in classical bits to quantum computing processor 102. Further, quantum states measured by quantum computing processor 102 can be read by classical computing processor 116 and classical computing processor 116 can store the measured quantum states as classical bits in classical registers. For example, the classical computing processor 116 may include or more hardware processor components, for example, including components such as programmable logic devices, microcontrollers, memory devices, and/or other hardware components, which may be configured to perform respective tasks described in the present disclosure. Coupled memory devices may be configured to selectively store instructions executable by one or more hardware processors. For example, a hardware processor may be a central processing unit (CPU), a graphics processing unit (GPU), a field programmable gate array (FPGA), an application specific integrated circuit (ASIC), another suitable processing component or device, or one or more combinations thereof. The processor may be coupled with a memory device. The memory device may include random access memory (RAM), read-only memory (ROM) or another memory device, and may store data and/or processor instructions for implementing various functionalities. The processor may execute computer instructions stored in the memory or received from another computer device or medium. Components of classical computer 116 are also described in more detail below with reference to FIG. 10. Classical computer 116 may be classical computer 41 shown and described with reference to FIG. 12.

The boundary operator is a linear operator that acts on a collection of high-dimensional binary points (e.g., simplices) and maps them to their boundaries. The concept of a simplical complex is derived from data-points embedded in some ambient space. A k-simplex is a collection of k+1 vertices forming a simple polytope of dimension k; e.g., 0-simplices are single points (zero-dimensional), 1-simplices are line segments (one-dimensional), 2-simplices are triangles (two-dimensional), and so on. A simplicial complex is a collection of such simplices (of any order), closed under adding all lower simplices, which are simplices obtained by removing one vertex (e.g., if a triangle is in a complex, then all three associated edge simplices are also in the complex and, recursively, so are all three associated points). Homology provides a linear-algebraic approach to extract, from simplicial complexes derived from the data, features that describe the “shape” of the data, such as the number of connected components, or holes (as in doughnuts), or voids (as in swiss cheese), or higher-dimensional holes/cavities.

Given a set of n data-points {xᵢ}ᵢ₌₀ⁿ⁻¹ in some space together with a distance metric [symbol] , a Vietoris-Rips simplicial complex is constructed by selecting a resolution/grouping scale ε that defines the “closeness” of the points with respect to the distance metric [symbol] , and then connecting the points that are a distance of ε from each other (i.e., connecting points xᵢ and xⱼ whenever [symbol] (xᵢ, xⱼ)≤ε, forming a so-called 1-skeleton). A k-simplex is then added for every subset of k+1 data-points that are pair-wise connected (i.e., for every k-clique, the associated k-simplex is added). The resulting simplicial complex is related to the clique-complex from graph theory.

Let Sₖ denote the set of k-simplices in the Vietoris-Rips complex Γ={Sₖ}ₖ₌₀ⁿ⁻¹, with sₖ∈ Sₖ written as [j₀, . . . , jₖ] where jᵢ is the ith vertex of sₖ. Let [symbol] ₖ denote an (ₖ₊₁ⁿ)-dimensional Hilbert space ((n choose k+1)-dimensional Hilber space), with basis vectors corresponding to each of the possible k-simplices (all subsets of size k+1). Further let [symbol] ₖ denote the subspace of [symbol] ₖ spanned by the basis vectors corresponding to the simplices in Sₖ, and let |sₖ [symbol] denote the basis state corresponding to sₖ∈Sₖ. Then, the n-qubit Hilbert space [symbol] ²ⁿ is given by [symbol] ²^{ⁿ}≅⊕ₖ₌₀ⁿ [symbol] ₖ. The boundary map (operator) on k-dimensional simplices ∂ₖ: [symbol] ₖ→ [symbol] ₖ₋₁ is a linear operator and can be defined by its action on the basis states as follows (also defined below in Eq. (1)):

$${\partial }_{k} \vert {s}_{k} 〉 = {\sum }_{l = 0}^{k - 1} {( - 1 )}^{l} \vert {s}_{k - 1} ( l ) 〉 ,$$

where |sₖ₋₁(l) [symbol] is the lower simplex obtained by leaving out vertex l (i.e., sₖ₋₁ has the same vertex set as sₖ except without jₗ). It is noted that, sₖ₋₁ is k−1-dimensional, one dimension less than sₖ. The factor (−1)^{l} produces the so-called oriented sum of boundary simplices, which keeps track of neighbouring simplices so that ∂ₖ₋₁∂ₖ|sₖ)=0, given that the boundary of the boundary is empty.

This boundary operator (also known as boundary map) can be used as one of the components in numerous applications, including but not limited to, differential equations, machine learning, computational geometry, machine vision and control systems. The quantum circuit 104 can simulate or represent the boundary operator on a quantum computer. In an embodiment, the boundary operator has a special structure in the form of a complete sum of fermionic creation and annihilation operators. In an embodiment, these operators pairwise anticommute to produce an [symbol] (n)-depth circuit that can exactly implement the boundary operator without any Trotterization or Taylor series approximation errors. Having fewer errors reduces the number of measurement shots required to obtain desired accuracies. In one or more embodiments, the boundary operator is represented as a sum of Pauli operators. Pauli operators can map to quantum primitives or gates in quantum computing that can perform operations on qubits.

Boundary operators (also known as boundary maps) are computational primitives used for the representation and analysis of graph and network analysis, machine vision, control systems, computational geometry, differential equations, finite element methods, and more. They are also used to bridge the gap between discrete representations, such as graphs and simplicial complexes, and continuous representations, such as vector spaces and manifolds. The graph Laplacians (including higher-order combinatorial Laplacians) can be constructed using the boundary operator. Laplacians of graphs and hypergraphs play a practical role in spectral clustering, a computationally tractable solution to the graph partitioning problem that is prevalent in applications such as image segmentation, collaborative recommendation, text categorization, and manifold learning. Graph Laplacians are implemented in graph neural network architectures, a recent set of neural network techniques for learning graph representations.

The boundary operator can also be used in Topological Data Analysis (TDA), as a linear operator that acts on a given set of simplices and maps them to their boundaries. TDA is a powerful machine learning and data analysis technique used to extract shape-related information of large data sets. TDA permits representing large volumes of data using a few global and interpretable features called Betti numbers. Classical algorithms for TDA and Betti number calculations are typically computationally expensive. While one known quantum algorithm proposed for TDA (or QTDA) may provably achieve exponential speed up over classical TDA algorithms under certain conditions, that quantum TDA (or QTDA) algorithm requires fault-tolerance, due to the need for a full Quantum Phase Estimation (which may be made worse by the embedded and repeated use of Grover's search).

In TDA, the data can be high dimensional, for example, with a data point having many attributes. TDA allows for interpretability of data and can be used in unsupervised learning where data can be grouped into subsets based on one or more criteria such as their characteristics or attributes. Persistent homology finds in data signature shapes that persist, e.g., local and/or global features in data. TDA or homology can include studying shapes in data, e.g., by finding number of connected components, holes, voids, and higher dimensional counterparts. Given a set of data-points in some ambient (possibly high-dimensional) space, TDA aims to extract a small set of robust and interpretable features that capture the “shape” of the dataset. Persistent Homology aims to compute these features at different scales of resolution, thus obtaining a set of local and global features to describe the data distribution topologically. These topological features are not only invariant under rotation and translation, but are also generically robust with respect to the data representation, the data sampling procedure, and noise. For these reasons, TDA can be a powerful tool used in many data applications.

TDA can be considered a “big data” algorithm that can consume massive datasets and reduce them to a handful of global and interpretable signature numbers, which can be used in predictions and analytics. Currently known approaches to quantum TDA can require or assume a fault-tolerant system and deep depth quantum circuits. In one or more embodiments, a technique described herein can provide one or more components such as quantum circuits for implementing a quantum machine learning (QML) algorithm with linear-depth complexity and provable exponential speedup on arbitrary input, providing a useful NISQ algorithm with quantum advantage. For example, a technique presented herein can aid in achieving NISQ-QTDA, a quantum topological data analysis algorithm that has an improved exponential speedup and a depth complexity of O(nlog(1/(δ∈))), where ∈ denotes the error tolerance.

In an embodiment, the boundary operator quantum circuit can be a component of a quantum homology algorithm implemented on a quantum computing processor. For example, the quantum circuit can simulate one or more boundary operators for quantum homology. In an embodiment, such quantum homology algorithm can be used for big data analysis, for example, to find useful features in a large and still growing data set. In an aspect, a boundary matrix is expressed in terms of boundaries (for example, edges) of simplices (for example, faces), and can involve exponentially many terms, e.g., many non-zero terms. In an embodiment, the quantum circuit can improve efficiency in boundary matrix operations used in quantum homology.

In an embodiment, a QTDA algorithm implemented with such a boundary operator quantum circuit can be more amenable to NISQ implementations. For example, the algorithm may have only an O(n)-depth quantum circuit, and thus has the potential to be an early useful NISQ algorithm that may provably achieve exponential speed up.

In one or more embodiments, the (generalized) boundary operator B can be represented in a novel tensor form, as a complete sum of fermionic creation and annihilation operators. In an embodiment, the standard technique of applying a Hermitian operator on a quantum computer can be implemented, namely executing the time-evolution unitary e^{-itB} for short time t and ‘solving’ for the second term of the Taylor series (−itB). The time-evolution can be approximated by Trotterization. Using this technique, with certain gate cancellations, an O(n)-depth circuit representation can be obtained for the boundary operator.

In another embodiment, an exact implementation of the boundary operator can be provided by a quantum circuit, which does not incur Trotteirzation errors. For example, in one or more embodiments, a technique is used or implemented (where it is called unitary partitioning) to exactly express the full (e.g., all k-simplices) Hermitian boundary operator as a unitary operator that has an efficient O(n)-depth construction in terms of quantum computing primitives. This short depth circuit, without evolution and Trotterization, analytically can implement the boundary operator, allowing for fewer measurement shots than the standard Hermitian-evolution technique. This can be instrumental in many downstream applications such as QTDA, in cohomology problems, quantum algorithms for finite element methods, solving partial differential equations, and potential quantum algorithms for machine vision and control systems.

The Boundary Operator and its Fermionic Representation

By way of example, the following description introduces the concept of boundary operators in the context of computational geometry and TDA in more detail. The description further explains the fermionic creation and annihilation operators, and presents a fermionic representation for the boundary operator. For completeness, a proof establishing its correctness is also described below.

Computational Geometry

In a quantum algorithm for topological data analysis (QTDA), simplices can be represented by strings of n bits. Each bit corresponds to a vertex, with zero indicating exclusion and one inclusion. On the quantum computer, the usual computational basis can directly map to simplices. There are 2ⁿ computational basis vectors, one for each unique n-bit binary string, written |sₖ [symbol] , where k indicates the number of vertices in the simplex (i.e., the number of ones in the binary string). There can be a difference in a way for how to index the bits of the binary string. Herein, this way is described explicitly and can refer to ‘counting from the left’ or ‘right’. Herein, the introduced indices are indexed from 0. In general, the quantum state vector (of length 2ⁿ) can be in a superposition of these basis vectors/simplices. In an aspect, core to the QTDA algorithm is the restricted boundary operator, defined by its action on k-dimensional simplices (among n vertices, hence the superscript (n) in the following):

$${\partial }_{k}^{( n )} \vert {s}_{k} 〉 = {\sum }_{l} {( - 1 )}^{l} \vert {s}_{k - 1} ( l ) 〉 , \qquad ( 1 )$$

where |sₖ [symbol] represents a simplex, and |sₖ₋₁(l) [symbol] is the simplex of one dimension less than |sₖ [symbol] with the same vertex set (containing n vertices), but leaving out the l^{th} vertex counting from the left.

Fleshing out the Restricted Boundary Operator

It helps to rewrite (1) without the use of index l, which hides some algorithmic steps, because l presupposes that the locations of the ones are known (i.e., which vertices are in a given simplex, e.g., l=0 refers to the first 1 in the string reading from left-to-right). Eq. (1) can be rewritten using index i:

∂ₖ⁽ⁿ⁾|sₖ [symbol] =Σᵢ₌₀ⁿ⁻¹δₛ_{ₖ}_{[i],1}(−1)^{Σ}^{ⱼ₌ᵢ₊₁}^{^{n−1}}^{s}^{ₖ}^{[f]}|sₖ₋₁(i) [symbol] , (2)

where it is now chosen to locate each bit counting from the right starting with index 0. The description here introduces the notation sₖ[i] to represent the i^{th} bit of the string. The description uses |sₖ₋₁(i) [symbol] to mean |sₖ [symbol] with the i^{th} vertex set to 0 (where i can be any bit index). All references to l can be replaced, including the implicitly required knowledge of the location of the last 1 (the sum across i simply runs from 0 to n−1). Below, this definition is illustrated with explicit examples.

In an aspect, ∂ₖ⁽ⁿ⁾'s action on a single simplex can be split into two cases depending on whether the last vertex, indexed n−1, is in the simplex or not. The absence or presence of this last vertex is represented by the bit sₖ[n−1] being 0 or 1, respectively. If sₖ[n−1]=0, the quantum state corresponding to this single simplex (call it |s_{k,0} [symbol] ) is a single computational basis state whose binary string has exactly k one's somewhere in it, except that the left most bit is zero. If this basis state is written as an exponentially long vector it consists of a column of 2ⁿ⁻¹ bits only one of which is 1 (at a location whose binary string consists of those k ones) followed by 2ⁿ⁻¹ zeros. This is similarly the case for |s_{k,1} [symbol] , but with the single 1 appearing in the second half of the column vector.

$$If \vert {s}_{k} 〉 = \vert {s}_{k , 0} 〉 for k \leq n - 1 , \qquad ( 3 )$$

$$\begin{matrix}{\partial }_{k}^{( n )} \vert {s}_{k , 0} 〉 = {\sum }_{i = 0}^{n - 1} {{δ}_{{s}_{k} [ i ] , 1} ( - 1 )}^{{\sum }_{j = i + 1}^{n - 1} {s}_{k} [ j ]} \vert {s}_{k - 1} ( i ) 〉 \\ = {\sum }_{i = 0}^{n - 2} {δ}_{{s}_{k} [ i ] , 1} {( - 1 )}^{{\sum }_{j = i + 1}^{n - 2} {s}_{k} [ j ]} \vert {s}_{k - 1} ( i ) 〉 \\ = ( \begin{matrix}{\partial }_{k}^{( n - 1 )} & 0 \\ 0 & 0\end{matrix} ) \vert {s}_{k , 0} 〉 .\end{matrix}$$

$$If \vert {s}_{k} 〉 = \vert {s}_{k , 1} 〉 for k \leq n , \qquad ( 4 )$$

$$\begin{matrix}{\partial }_{k}^{( n )} \vert {s}_{k , 1} 〉 = {\sum }_{i = 0}^{n - 1} {{δ}_{{s}_{k} [ i ] , 1} ( - 1 )}^{{\sum }_{j = i + 1}^{n - 1} {s}_{k} [ j ]} \vert {s}_{k - 1} ( i ) 〉 \\ = \vert {s}_{k - 1} ( n - 1 ) 〉 + ( - 1 ) \\ {\sum }_{i = 0}^{n - 2} {δ}_{{s}_{k} [ i ] , 1} {( - 1 )}^{{\sum }_{j = i + 1}^{n - 2} {s}_{k} [ j ]} \vert {s}_{k - 1} ( i ) 〉 \\ = ( \begin{matrix}0 & {P}_{k - 1}^{( n - 1 )} \\ 0 & 0\end{matrix} ) \vert {s}_{k , 1} 〉 - 1 ( \begin{matrix}0 & 0 \\ 0 & {\partial }_{k - 1}^{( n - 1 )}\end{matrix} ) \vert {s}_{k , 1} 〉 ,\end{matrix}$$

where Pₖ₋₁⁽ⁿ⁻¹⁾ is the projection on to the computational basis states of n−1 qubits whose binary strings contain exactly k−1 ones. It can be seen how the block diagonal notation is allowing for removing or leaving alone the k^{th} one precisely in the n^{th} position. In this particular equation, since one may only act on |s_{k,1} [symbol] and remove the n^{th} vertex, the projection could be replaced by the identity operator.

Fermionic Boundary Operator

Fermionic fields obey Fermi-Dirac statistics, which means that they admit a mode expansion in terms of creation and annihilation oscillators that anticommute. In one or more embodiments, fermionic creation and annihilation operators can be mapped to Pauli spin operators. The mapping can work both way. For example, Pauli spin operators can be mapped to fermionic creation and annihilation, for example, depending on a starting premise. The Jordan-Wigner transformation is one such mapping. In one or more embodiments, a system and/or method can make use of it to express the boundary matrix.

The restricted boundary operator given in Eq. (1) is not in a form that can be easily executed on a quantum computer, nor does it act on all orders, k, at the same time. In particular, it is a high-level description of the action of the boundary operator on a single generic k-dimensional simplex with the location of the ones assumed to be known. In one or more embodiments, a novel representation is proposed that realizes the full boundary operator as a matrix. Furthermore, this representation in an embodiment is in tensor product form composed of quantum computing primitives that directly map to quantum gates in the quantum circuit model.

To begin, define the operator:

$${Q}^{+} := \frac{1}{2} ( {σ}_{x} + i {σ}_{y} ) = ( \begin{matrix}0 & 1 \\ 0 & 0\end{matrix} ) . \qquad ( 5 )$$

This way, the full boundary operator can be written in terms of the above operator:

$$\begin{matrix}{\partial }^{( n )} := {σ}_{z} ⊗ … ⊗ {σ}_{z} ⊗ {Q}^{+} + \\ {σ}_{z} ⊗ … ⊗ {σ}_{z} ⊗ {Q}^{+} ⊗ I \\ ⋮ + \\ {σ}_{z} ⊗ {Q}^{+} ⊗ I ⊗ … + \\ {Q}^{+} ⊗ I ⊗ I ⊗ … \\ = {\sum }_{i = 0}^{n - 1} {a}_{i} ,\end{matrix} \qquad ( 6 )$$

where the αᵢ are the Jordan-Wigner Pauli embeddings corresponding to the n-spin fermionic annihilation operators. In another embodiment, for example, other than the Jordan-Wigner mapping of fermionic operators, other embeddings (e.g., Bravyi-Kitaev) may also be contemplated, for example, via translation between the different embeddings. In yet another embodiment, since simplicial homology can be recast in terms of these fermionic operators, other geometric structures can be explored under this light. To be explicit, αᵢ is the antisymmetric annihilation operator on mode/orbital i (indexed from the right, starting at zero):

$$\begin{matrix}{α}_{i} := {\underbrace{{σ}_{z} ⊗ … ⊗ {σ}_{z}}}_{n - ( i + 1 )} ⊗ {Q}^{+} ⊗ {\underbrace{I ⊗ … ⊗ I}}_{i} \\ = {σ}_{z}^{⊗ ( n - ( i + 1 ) )} ⊗ {Q}^{+} ⊗ {I}^{⊗ i} ,\end{matrix} \qquad ( 7 )$$

$$\{ {a}_{i} , {a}_{j}^{†} \} = {δ}_{ij} {I}^{⊗ n} . \qquad ( 8 )$$

When Eq. (6) is realized in matrix form, where the rows' and columns' integer indices (counting from left to right and top to bottom, beginning at zero) are translated into binary, the meaning of these strings correspond exactly to the simplex strings introduced above. Recall, a one at bit i of the simplex string (counting from the right, starting from zero) corresponds to selecting the i^{th} vertex.

The following result can be shown:

Theorem 1. The full boundary operator as defined in Eq. (6) is a sum over the restricted boundary operators over simplices of each dimension as defined above as follows

∂⁽ⁿ⁾=Σₖ₌₁ⁿ∂ₖ⁽ⁿ⁾. (9)

Remark. A simple sum (as opposed to a direct sum) can be used because the definition of ∂ₖ has been extended to a common vertex space of size n. The rewriting constructs the full boundary operator in one step and the individual ∂ₖ's do not feature at all. To recover the ∂ₖ's one would project into the appropriate space, which is a step in implementing QTDA on quantum computers. The index i of the aᵢ fermionic operators indicates which qubit out of n is acted upon by Q⁺ (counting from the right) and does not involve ∂ₖ (e.g., there is no k dependence).

Proof. The proof proceeds by induction. A recurrence relation can be set up first as follows.

Recurrence Relation: Equation or Eq. (6) is amenable to efficient quantum circuit construction as shown below. It can be further shown that Eq. (6) is valid and correctly implements the high level description of Eq. (9). A way to prove equation (9) is by noticing that the left hand side satisfies the following recurrence relation and then connecting the recurrence relation to the right hand side of Eq. (9):

∂⁽ⁿ⁾=Q⁺⊗l^{⊗(n-1)}+σ_{z}⊗∂⁽ⁿ⁻¹⁾ (10)

∂⁽¹⁾=Q⁺.

It helps to write Eq. (10) in block diagonal form:

$${\partial }^{( n )} = ( \begin{matrix}+ 1 \cdot {\partial }^{( n - 1 )} & {I}^{⊗ ( n - 1 )} \\ 0 & - 1 \cdot {\partial }^{( n - 1 )}\end{matrix} ) \qquad ( 11 )$$

and consider the action of ∂⁽ⁿ⁾ in terms of ∂⁽ⁿ⁻¹⁾.

The operator ∂⁽ⁿ⁻¹⁾ acts on vectors of size 2ⁿ⁻¹, while ∂⁽ⁿ⁾ acts on vectors of size 2ⁿ. The vector of size 2ⁿ can be seen as two halves of size 2ⁿ⁻¹. The top half includes simplices where the n^{th} vertex is not in the simplex. The bottom half corresponds to a ‘copy’ of the n−1 space but now with the n^{th} vertex selected. For example, edges in the upper half become triangles in the lower half, since the n^{th} vertex is added. The top-left block of ∂⁽ⁿ⁾ in Eq. (11) is ∂⁽ⁿ⁻¹⁾ acting on the ‘top-half’ simplices, where the n^{th} vertex is not selected (sₖ[n−1]=0 and k has to be strictly less than n) and returns simplices (the boundaries) in the top half (since taking the boundary does not add the n^{th} vertex). The top-right block (j^{⊗(n-1)}) acts on simplices in the bottom half (sₖ[n−1]=1) and returns simplices in the top half, which corresponds to simply removing the n^{th} vertex and leaving everything else the same (hence the identity operator). The bottom-right block acts on simplices in the bottom half (sₖ[n−1]=1) and returns simplices in the bottom half, corresponding to those returned by taking the boundary operator acting on the first n−1 vertices and leaving the n^{th} vertex selected. The bottom returned vertices has a multiplication by −1 because acting on the first n−1 vertices by ∂⁽ⁿ⁻¹⁾ does not factor in the extra minus one from the n^{th} vertex in the definition shown in Eq. (2).

Inductive Proof of Simplex Action:

Eq. (9) can be proven via induction. The base case, ∂⁽¹⁾=∂₁⁽¹⁾ takes the single vertex vector to the null vector. It can be assumed that ∂⁽ⁿ⁾ for n≥1 implements the sum of restricted boundary operators of Eq. (9) up to n, and that assumption can be used to show that ∂ₙ₊₁ correctly implements the sum up to n+1, i.e., that

∂⁽ⁿ⁺¹⁾=Σₖ₌₁ⁿ⁺¹∂ₖ⁽ⁿ⁺¹⁾. (12)

From Eq. (11), the left hand side of Eq. (12) is

$${\partial }^{( n + 1 )} = ( \begin{matrix}{\partial }^{( n )} & {I}^{⊗ ( n )} \\ 0 & - 1 \cdot {\partial }^{( n )}\end{matrix} ) , \qquad ( 13 )$$

and from the inductive assumption of Eq. (9), this becomes

$${\partial }^{( n + 1 )} = ( \begin{matrix}{\sum }_{k = 1}^{n} {\partial }_{k}^{( n )} & {I}^{⊗ n} \\ 0 & - {\sum }_{k = 1}^{n} {\partial }_{k}^{( n )}\end{matrix} ) . \qquad ( 14 )$$

The right hand side of Eq. (12) contains terms of the form ∂ₖ⁽ⁿ⁺¹⁾. All ∂ₖ⁽ⁿ⁺¹⁾ act on n+1 vertices, so in matrix form they are all of the same dimension. From Eq. (3) and Eq. (4), there can be

$${\partial }_{k}^{( n + 1 )} \vert {s}_{k , 0} 〉 = ( \begin{matrix}{\partial }_{k}^{( n )} & 0 \\ 0 & 0\end{matrix} ) \vert {s}_{k , 0} 〉 , 1 \leq k \leq n , \qquad ( 15 )$$

$${\partial }_{k}^{( n + 1 )} \vert {s}_{k , 1} 〉 = ( \begin{matrix}0 & {P}_{k - 1}^{( n )} \\ 0 & - 1 \cdot {\partial }^{( n )}\end{matrix} ) \vert {s}_{k , 1} 〉 , 1 \leq k \leq n + 1. \qquad ( 16 )$$

Now since any |s [symbol] =Σₖ|sₖ [symbol] =Σₖ(|s_{k,0} [symbol] +|s_{k,1} [symbol] ) and the matrix in Eq. (15) takes |s_{k,1} [symbol] to the null vector:

$$( \begin{matrix}{\partial }_{k}^{( n )} & 0 \\ 0 & 0\end{matrix} ) \vert {s}_{k , 1} 〉 = 0 ,$$

while the matrix in Eq. (16) similarly takes |s_{k,0} [symbol] to the null vector:

$$( \begin{matrix}0 & {P}_{k - 1}^{( n )} \\ 0 & - 1 \cdot {\partial }_{k - 1}^{( n )}\end{matrix} ) \vert {s}_{k , 0} 〉 = 0 ,$$

Eq. (15) and Eq. (16) can be combined, while paying attention to different values of k:

$${\partial }_{1}^{( n + 1 )} = \begin{matrix}( \begin{matrix}{\partial }_{1}^{( n )} & {P}_{0}^{( n )} \\ 0 & 0\end{matrix} ) , & k = 1 ,\end{matrix} \qquad ( 17 )$$

$${\partial }_{k}^{( n + 1 )} = \begin{matrix}( \begin{matrix}{\partial }_{k}^{( n )} & {P}_{k - 1}^{( n )} \\ 0 & - 1 \cdot {\partial }_{k - 1}^{( n )}\end{matrix} ) , & 2 \leq k \leq n\end{matrix} , \qquad ( 18 )$$

$${\partial }_{n + 1}^{( n + 1 )} = \begin{matrix}( \begin{matrix}0 & {P}_{n}^{( n )} \\ 0 & - 1 \cdot {\partial }_{n}^{( n )}\end{matrix} ) , & k = n + 1 ,\end{matrix} \qquad ( 19 )$$

where P₀ⁿ=|0 . . . 0 [symbol] [symbol] 0 . . . 0| (n zeroes) and Pₙ⁽ⁿ⁾=1 . . . 1 [symbol] [symbol] 1 . . . 1| (n ones). Note that ∂ₙ₊₁⁽ⁿ⁺¹⁾ produces no top-left block and ∂₁ⁿ⁺¹⁾ produces no bottom-right block.

Therefore, the right hand side of Eq. (12) is:

$${\sum }_{k = 1}^{n + 1} {\partial }_{k}^{( n + 1 )} = ( \begin{matrix}{\sum }_{k = 1}^{n} {\partial }_{k}^{( n )} & {I}^{⊗ n} \\ 0 & - {\sum }_{k = 1}^{n} {\partial }_{k}^{( n )}\end{matrix} ) , \qquad ( 20 )$$

$$since {\sum }_{k = 0}^{n} {P}_{k}^{( n )} = {I}^{⊗ n} .$$

Therefore the right-hand side is equal to the left-hand side Eq. (14).

With the proof in hand, it can be understood as to why Eq. (6) and its recursive form Eq. (10) can only produce Eq. (1) in summation form of Eq. (9). In particular, ∂ₖ on a simplex with one more potential vertex (n+1) is related to both ∂ₖ and ∂ₖ₋₁ on the original number of vertices (n). Therefore, in an embodiment, a system (and/or method and/or apparatus) can implement the full chain of sums to build up a recursive construction, where the system can sequentially add one vertex at a time, which then makes a quantum-implementable tensor definition possible.

Unitary Circuit

The boundary operator above is not Hermitian. To work with a version that is Hermitian, an embodiment for implementing a quantum circuit can add the Hermitian conjugate of the boundary operator to itself. Every Q⁺ in the tensor product now becomes σₓ=Q⁺+(Q⁺)^{†}. Hence, the full Hermitian boundary operator is

$$\begin{matrix}B = \partial + {\partial }^{†} & = {σ}_{z} ⊗ … ⊗ {σ}_{z} ⊗ {σ}_{x} \\ & + {σ}_{z} ⊗ … ⊗ {σ}_{z} ⊗ {σ}_{x} ⊗ I \\ & ⋮ \\ & + {σ}_{z} ⊗ {σ}_{x} ⊗ I ⊗ … \\ & + {σ}_{x} ⊗ I ⊗ I ⊗ … \\ & = {\sum }_{i = 0}^{n - 1} {Q}_{i} ,\end{matrix} \qquad ( 21 )$$

where I denotes the single-qubit identity operator, and

Qᵢ:=αᵢ+αᵢ^{†}, (22)

with αᵢ as defined in Eq. (7). This, Qᵢ is a Kronecker product of n Pauli matrices, of which the n−(i+1) leftmost are σ_{z}. The goal can now be to construct a unitary circuit to implement either B or exp(iBt) (depending on the application). Towards this end, it is useful to note that:

Lemma 1 The Q,'s pairwise anticommute: {Qᵢ, Qⱼ}=0 for i≠j.

Proof. The mixed-product identity for the Kronecker product is

(A⊗B)·(C⊗D)=(AC)⊗(BD). (23)

Hence, there can be (assuming without loss of generality that i>j so that there are more σ_{z} matrices in Qⱼ)

$$\{ {Q}_{i} , {Q}_{j} \} = \{ {\underbrace{{σ}_{z} ⊗ ⋯ ⊗ {σ}_{z}}}_{n - ( i + 1 )} ⊗ {σ}_{x} ⊗ {\underbrace{I ⊗ ⋯ ⊗ I}}_{i} , {\underbrace{{σ}_{z} ⊗ ⋯ ⊗ {σ}_{z}}}_{n - ( j + 1 )} ⊗ {σ}_{x} ⊗ {\underbrace{I ⊗ ⋯ ⊗ I}}_{j} \} . since \{ {σ}_{ℓ} , {σ}_{k} \} = 2 {δ}_{ℓ k} I and [ {σ}_{k} , I ] = 0 \qquad ( 24 )$$

for any k=x, y, z, Eq. (24) immediately yields the result.

Any real linear combination of pairwise anticommuting Pauli operators can be unitarily equivalent to a single Pauli operator, up to some rescaling. One can think of this as a generalization of the Bloch sphere to more than three Pauli operators. Moreover, the unitary that maps the linear combination to the single Pauli operator can be efficiently constructed. This technique can reduce the number of distinct terms in Hamiltonians to be simulated using variational quantum eigensolvers, in which context it is known as unitary partitioning.

For neighbouring Q's Qᵢ₋₁ and Qᵢ,

$$\begin{matrix}- i {Q}_{i - 1} {Q}_{i} & = - i {\underbrace{( {σ}_{z} ⊗ ⋯ ⊗ {σ}_{z}}}_{n - i} ⊗ {σ}_{x} ⊗ {\underbrace{I ⊗ ⋯ ⊗ I )}}_{i - 1} \cdot {\underbrace{( {σ}_{z} ⊗ ⋯ ⊗ {σ}_{z}}}_{n - ( i + 1 )} ⊗ {σ}_{x} ⊗ {\underbrace{I ⊗ ⋯ ⊗ I )}}_{i} \\ & = - {iI}^{⊗ ( n - ( i + 1 ) )} ⊗ {σ}_{z} {σ}_{x} ⊗ {σ}_{x} ⊗ {I}^{⊗ ( i - 1 )} \\ & = - {iI}^{⊗ ( n - ( i + 1 ) )} ⊗ i {σ}_{y} ⊗ {σ}_{x} ⊗ {I}^{⊗ ( i - 1 )} \\ & = {Y}_{i} {X}_{i - 1 ′} ,\end{matrix} \qquad ( 25 )$$

where Xᵢ₋₁ and Yᵢ are, respectively,

Xᵢ₋₁=l^{⊗(n-i)}⊗σₓ⊗l^{⊗(i-1)}, (26)

Yᵢ=l^{⊗(n-(i+l))}⊗σ_{y}⊗l^{⊗i}. (27)

Hence, −iQᵢ₋₁Qᵢ is itself a Pauli operator, and commutes with all Pauli terms in B except for Qᵢ₋₁ and Qᵢ. Therefore, a rotation generated by −iQᵢ₋₁Qᵢ only affects those two terms. For an arbitrary linear combination αQᵢ+βᵢ₋₁ for real α and β, define the following rotation generated by −iQᵢ₋₁Qᵢ:

$${R}_{i} ≡ exp ( \frac{{Q}_{i - 1} {Q}_{i}}{2} atan 2 ( α , β ) ) = exp ( \frac{i {Y}_{i} {X}_{i - 1}}{2} atan 2 ( α , β ) ) . \qquad ( 28 )$$

It can be shown that Rᵢ's adjoint action on the linear combination is

Rᵢ(αQᵢ+βQᵢ₋₁)Rᵢ^{†}=\sqrt{α²+β²}Qᵢ₋₁ (29)

Therefore, the system can map B, which as given in Eq. (21) is the sum of all of the Qᵢs, to a single Qᵢ via a sequence of such rotations as follows:

$$\begin{matrix}B = {\sum }_{i = 0}^{n - 1} {Q}_{i} & {⟶}^{{R}_{n - 1} with α = 1 , β = 1} & \sqrt{2} {Q}_{n - 2} + {\sum }_{i = 0}^{n - 3} {Q}_{i} \\ & {⟶}^{{R}_{n - 2} with α = \sqrt{2} , β = 1} & \sqrt{3} {Q}_{n - 3} + {\sum }_{i = 0}^{n - 4} {Q}_{i} \\ & {⟶}^{{R}_{n - 3} with α = \sqrt{3} , β = 1} & \sqrt{4} {Q}_{n - 4} + {\sum }_{i = 0}^{n - 5} {Q}_{i} \\ & ⋮ & \\ & {⟶}^{{R}_{2} with α = \sqrt{n - 2} , β = 1} & \sqrt{n - 1} {Q}_{1} + {Q}_{0} \\ & {⟶}^{{R}_{3} with α = \sqrt{n - 1} , β = 1} & \sqrt{n} {Q}_{0} ,\end{matrix} \qquad ( 30 )$$

where each arrow represents an application of Rᵢ as in Eq. (28) with the given values of α and β. Hence, the system can map B to \sqrt{n}Q₀=\sqrt{n}X₀, i.e., a single-qubit Pauli σₓ, via n−1 rotations generated by two-qubit Paulis YᵢXᵢ₋₁.

Let R denote this entire sequence of rotations, i.e.,

R=Πᵢ₌₍ₙ₋₁₎ⁱ⁼¹Rᵢ. (31)

In terms of R, the above result is

RBR^{†}=\sqrt{n}X₀, (32)

which implies that

B=\sqrt{n}R^{†}X₀R. (33)

Based on Eq. (33), a boundary map quantum circuit can be constructed or built, e.g., for a QTDA use case. Since R^{†}X₀R is unitary, it can be implemented as a quantum circuit, and to obtain B the constant of proportionality can be included during classical postprocessing.

In one or more embodiments, for other use cases (such as propagators in differential equations), the time evolution of B can be implemented. For these cases, in order to implement the time-evolution generated by B for a time t, an embodiment of a quantum circuit can apply R, then implement the time-evolution generated by \sqrt{n}X₀ for time t, and then invert R:

e^{-iBt}=R^{†}e^{-i\sqrt{n}X}^{₀}^{t}R, (34)

where R and Rᵢ are as defined in Eq. (28) and Eq. (31).

Remark. The cost of implementing this evolution is independent of t, since the system can classically precompute \sqrt{n}t mod 2π and implement the rotation generated by X₀ through this angle.

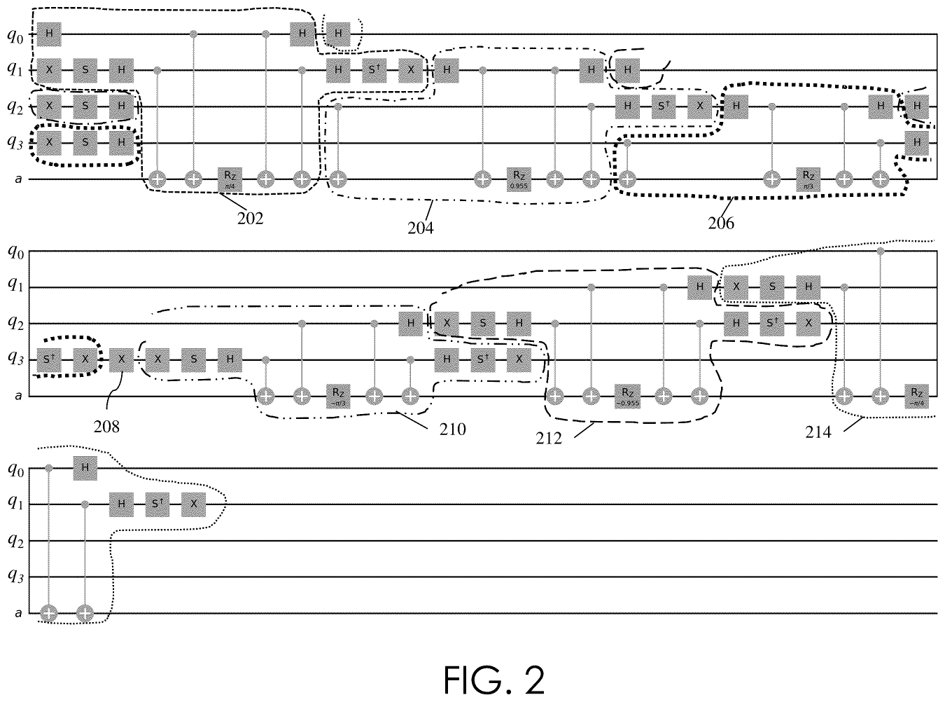

FIG. 2 shows an example quantum circuit simulating a boundary operator for a given simplicial complex in an embodiment. In this example, the given simplicial complex has n vertices, where n is 4. In an embodiment, Eq. (33) given above can be used to build the quantum circuit. For example, terms in Eq. (33) can translate to quantum circuit components, e.g., a linear combination of Pauli gates. For instance, the quantum circuit performs rotations around a string of two Pauli gates (Pauli X and Pauli Y), followed by Pauli X gate, followed by reverse of the two X and Y Pauli string rotations. The quantum circuit can have an O(n)-depth construction in terms of quantum computing primitives. For example, in an embodiment, the number of gates in the quantum circuit can be some constant factor multiplied by the number of qubits (vertices or nodes). The quantum circuit can include n qubits and an ancillary qubit (an extra qubit, also referred to an ancilla bit). The n qubits can correspond to n vertices of a simplex and via superposition of the entire simplicial complex, on which the boundary operator or map acts. For instance, through superposition, n vertices can be “reused” by each simplex in the simplicial complex. Each vertex can be assigned a qubit out of the n qubits in the quantum circuit. At the input, the n qubits are encoded with information. For example, the n qubits loaded with information (e.g., simplicial complex information) can be loaded with a probe simplicial complex. The ancilla bit at the input can be 10>.

Referring to Eq. (33), the quantum gates shown at 202, 204, 206 construct the rotations represented as “R” (e.g., concatenation of Rᵢ's, i=1 to n−1), where n=4; the CNOT (controlled NOT) gate shown at 208 represents the term “X₀”; and the gates shown at 210, 212, 214 represent the term “R^{†}” (e.g., concatenation of R^{†}ᵢ's, i=1 to n−1).

For example, Rᵢ implements Pauli Yᵢ and Xᵢ₋₁ rotations applied to the i-th and (i−1)-th qubits, respectively. In an embodiment, a quantum circuit can implement this rotation around the eigenstates of Pauli X and Y by applying a change of bases onto the z-axis, and rotating about the z-axis by a given angle. A change of basis from X to z-axis for (i−1)-th qubit can be implemented by applying an H-gate to the (i−1)-th qubit. A change of basis from Y to z-axis for i-th qubit can be implemented by applying X-gate, S-gate, and H-gate to the i-th qubit. A rotation around the z-axis can be implemented by applying a rotation gate about the z-axis by a given angle.

For instance, each of 202, 204 and 206 shows rotations, Rᵢ according to Eq. (28), for qubit i, where i=1 to n−1 (see Eq. (31)). Referring to 202 (e.g., for i=1), by way of example, H-gate on q₀ performs change of basis of qubit i−1 (Xᵢ₋₁ in Eq. (28)) to z-axis; X-gate, S-gate, H-gate on q₁ perform change of basis of qubit i (Yᵢ in Eq. (28)) to z-axis; CNOT-gate on q₀ and ancilla bit, and CNOT-gate on q₁ and ancilla bit prepare for rotation about z-axis, e.g., a CNOT-gate entangles two qubits; R_{z}-gate (or Z-gate) implements rotation by a given angle (atan2(α, β), e.g., see Eq. (30)); the rest of the gates shown in 202 perform changing back of basis or undoing the changes of basis. As shown by 202, 204 and 206, the set of gates shown at 202 repeat for n−1 iterations, for any n qubits (e.g., vertices of a simplicial complex or nodes in a graph). Each iterations operates on two-qubits, i-th and (i−1)-th qubits.

Briefly, X-gate rotates the qubit state by w radians (180°) about the x-axis. S-gate rotates the qubit state by π/2 radians (90°) about the z-axis. Z-gate rotates the qubit state by π radians (180°) about the z-axis. H-gate rotates the qubit state by w radians (180°) about an axis diagonal in the x-z plane, which can be equivalent to an X-gate followed by a π/2 rotation about the y-axis. Controlled-NOT (CNOT)-gate applies an X-gate to the target qubit if the control qubit is in state |1>.

For instance, a quantum circuit simulating a boundary operator can include n input qubit registers (or qubits), an ancilla qubit register (or qubit), n−1 sets of first quantum gates configured to perform two qubit Pauli Xᵢ₋₁ and Yᵢ rotations applied to the (i−1)-th and i-th qubits, respectively, where i can be 1 to n−1, an X-gate configured to act on (n−1)-th qubit, and a series of n−1 sets of second quantum gates configured to reverse the two qubit rotations performed by the n−1 sets of first quantum gates.

The resulting transformation or mapping represented in the quantum states of the qubits can be communicated to another one or more quantum circuits, to be used in computation. For instance, in an embodiment, the quantum circuit simulating a boundary operator can be used as a component of a series of quantum circuits, implementing TDA. In another embodiment, the quantum circuit simulating a boundary operator can be used as a component of a series of quantum circuits implementing another quantum algorithm.

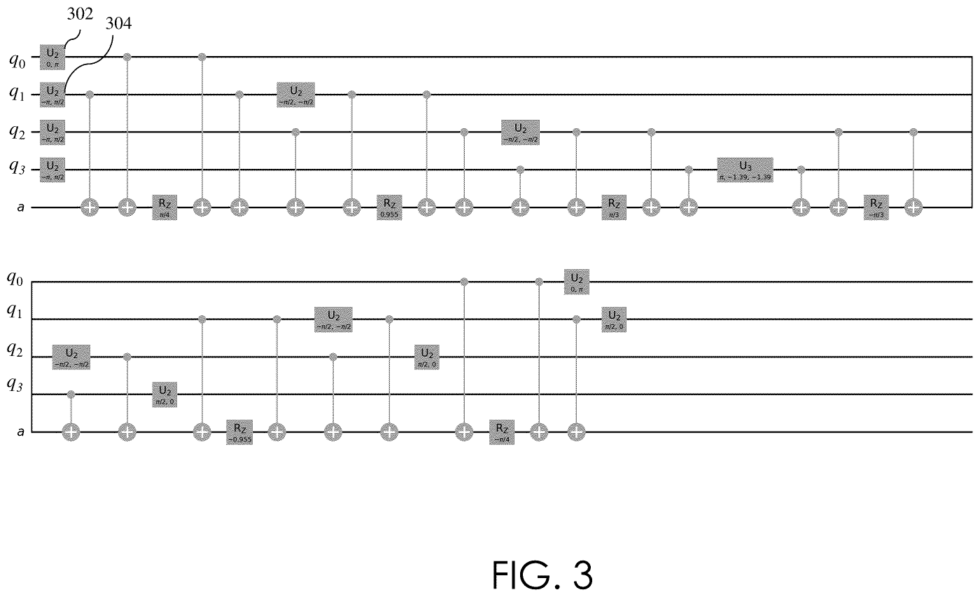

FIG. 3 shows an optimized example quantum circuit of FIG. 2, optimized using unitary operators in an embodiment, where a series of gates is combined to obtain a simpler unitary gate, and also cancellation of gates. As with the quantum circuit shown in FIG. 2, in an embodiment, the quantum circuit has an O(n)-depth construction in terms of quantum computing primitives. The quantum circuit can include n qubits and an ancillary qubit (an extra qubit, also referred to an ancilla bit). The n qubits can correspond to n vertices of a simplex and via superposition of the entire simplicial complex, on which the boundary operator or map acts. For instance, through superposition, n vertices can be “reused” by each simplex in the simplicial complex. In an embodiment, each vertex of the simplicial complex can be assigned a quibit of n qubits in the quantum circuit. In comparison to the circuit shown in FIG. 2, a set of, or a sequence of adjacent single qubit gates can be transformed or optimized to a unitary operator. For example, shown at 302, an H-gate on q₀ can be transformed to a unitary operator. Similarly, shown at 304, X-gate, S-gate, H-gate on q₁ can be transformed to a unitary operator. Adjacent H-gates (H-gates next to one another) can be cancelled. Three adjacent X-gates can be simplified to one X-gate.

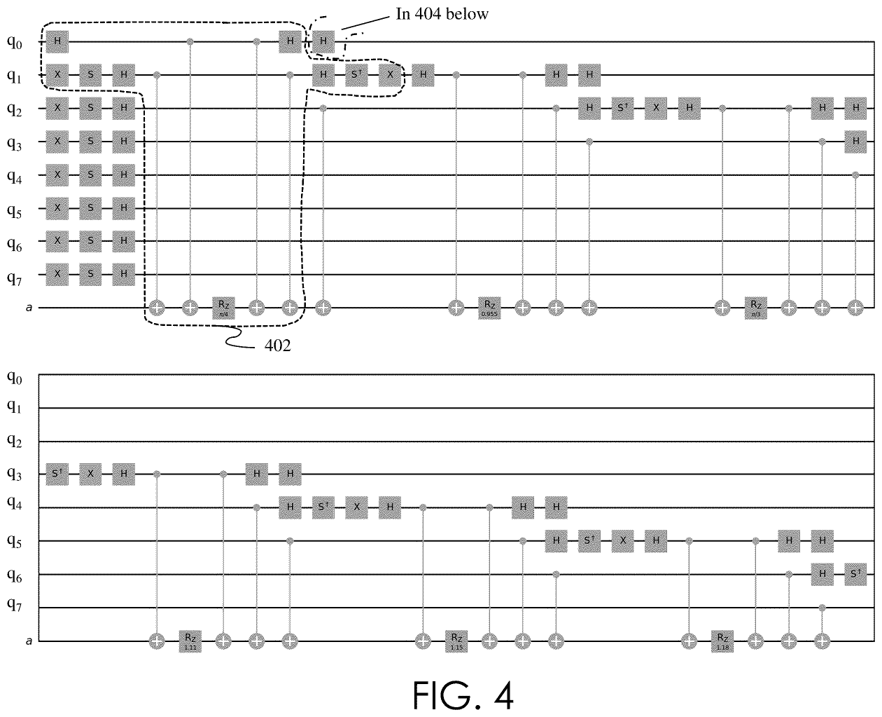

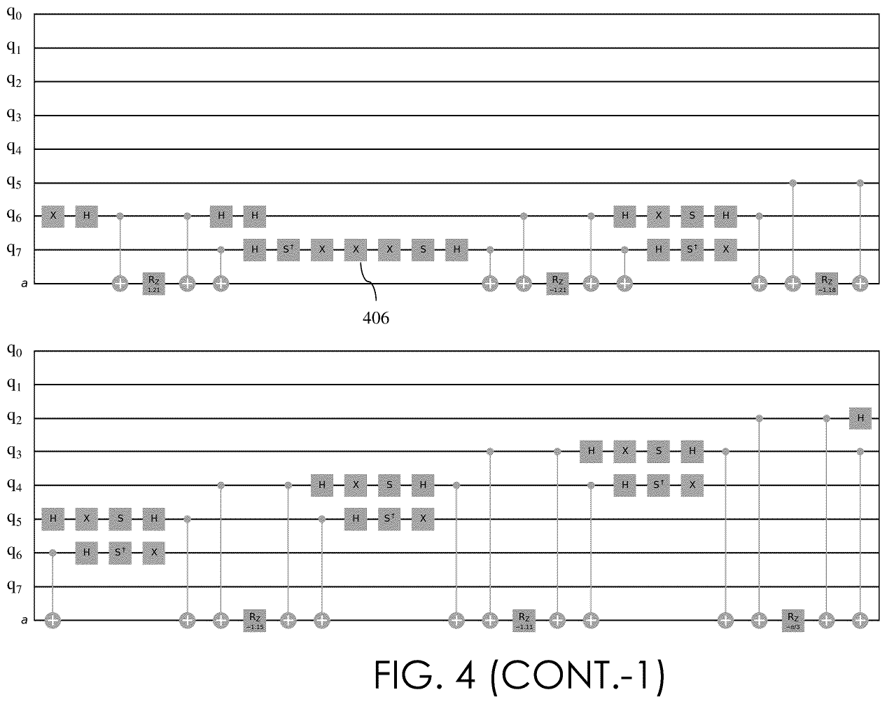

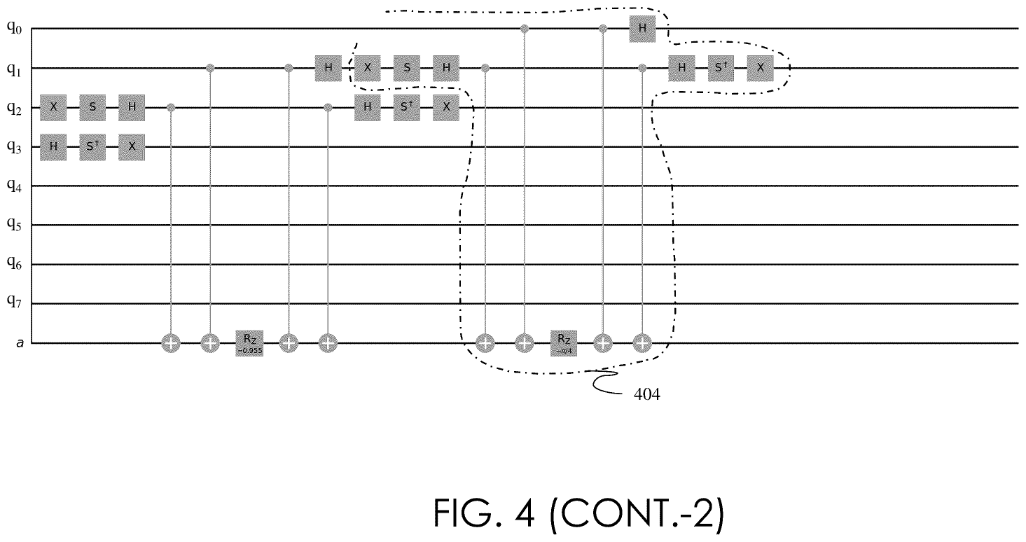

FIG. 4 illustrates a quantum circuit that can simulate a boundary operator, e.g., given a simplicial complex with n vertices, where n is 8. The quantum circuit has an O(n)-depth construction in terms of quantum computing primitives. The quantum circuit can include n qubits and an ancillary qubit (an extra qubit, also referred to an ancilla bit). For example, the n qubits can correspond to n vertices of a simplex and via superposition of the entire simplicial complex, on which the boundary operator or map acts. For instance, through superposition, n vertices can be “reused” by each simplex in the simplicial complex. Each vertex of the simplicial complex can be assigned a quibit of n qubits in the quantum circuit. The quantum circuit shown in FIG. 4 includes n−1 sets of gates, a set of gates operating with i-th and (i−1)-th qubits. For example, the quantum gates shown at 402 represent “R”, where i=1. Concatenation of such quantum gates are shown for i=1 to n−1, followed by the CNOT-gate (control NOT) shown at 406, which represents the term “X₀”. The quantum gates shown at 404 represent the term “R^{†}”, for i=1. Again, concatenation of such quantum gates is shown for i=1 to n−1. As shown, the quantum gates in the sets at 402 and 404 operate on q₁ and q₀.

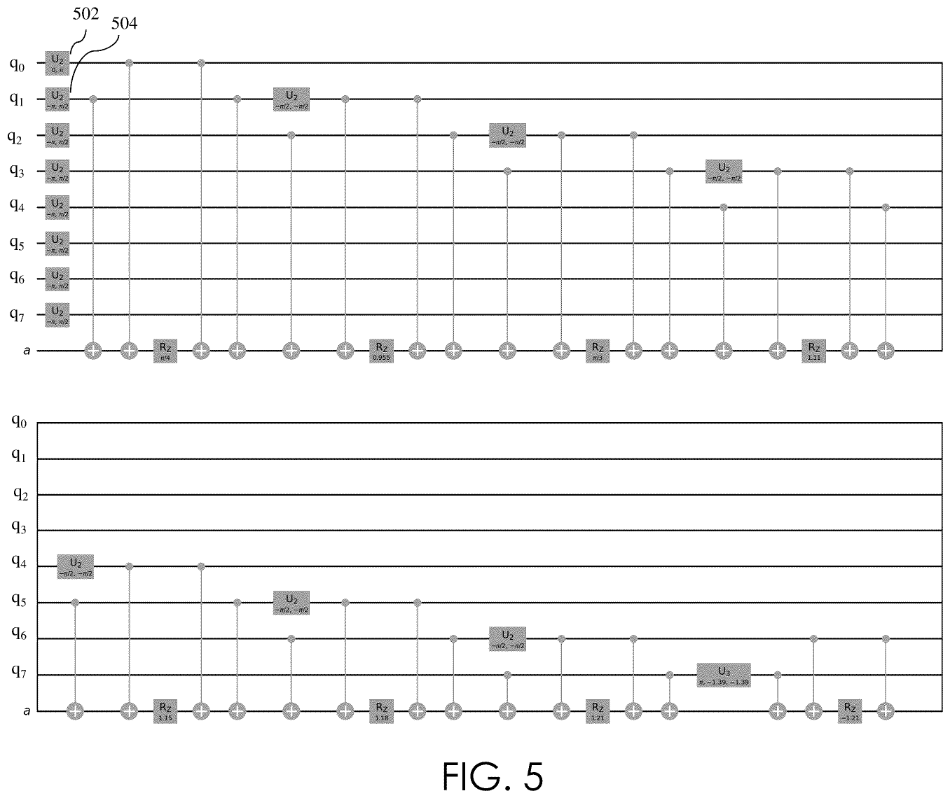

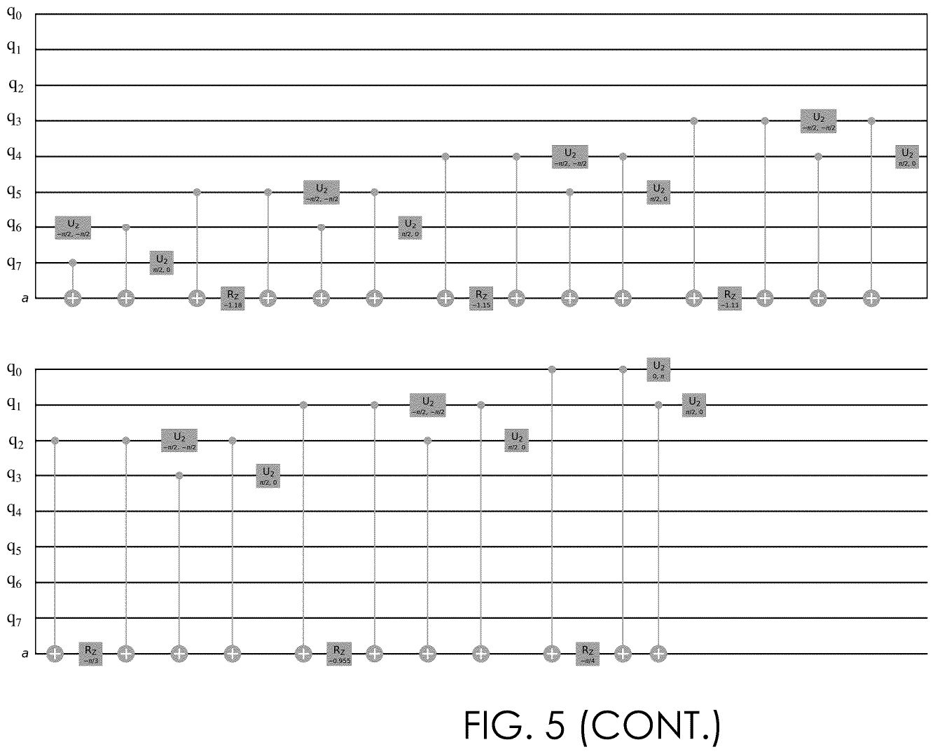

FIG. 5 illustrates an optimized version of the quantum circuit shown in FIG. 4 in an embodiment, where a series of gates is combined to obtain a simpler unitary gate. Gate cancellation where applicable can also be performed for further simplification. The quantum circuit has an O(n)-depth construction in terms of quantum computing primitives. The quantum circuit can include n qubits and an ancillary qubit (an extra qubit, also referred to an ancilla bit). The n qubits correspond to n vertices of a simplex or simplicial complex for which a boundary operator or map is being constructed. Each vertex of the simplicial complex can be assigned a quibit of n qubits in the quantum circuit. Similarly to the optimization of 4 qubit circuit shown in FIG. 2 and FIG. 3, the circuit in FIG. 5 shows a set of, or a sequence of single qubit gates, which are transformed or optimized to a unitary operator. Two adjacent H-gates can be cancelled. For example, shown at 502, an H-gate on q₀ can be transformed to a unitary operator. Similarly, shown at 504, X-gate, S-gate, H-gate on q₁ can be transformed to a unitary operator.

In an embodiment, because the quantum circuit is an exact representation of the boundary operator or map (an exact implementation), for example, without approximation, there are no trotterization errors and no approximation errors. For example, previous works that use approximation for implementing a large matrix via techniques such as sparse data access, may introduce errors including approximation errors into the representation.

Depth and Shots in QTDA Use Case

The above unitary form of the boundary operator shown as Eq. (33) has depth [symbol] (n) since there are 2(n−1) rotations and one X₀. To be precise, the dependence on n is contained in R, which is a sequence of n−1 two-qubit rotations, so in total there can be 2(n−1) two-qubit rotations. For achieving the [symbol] (n) depth, each Pauli rotation (involving two qubits) can be implemented in constant depth. For example, the standard way to evolve a single Pauli string is to change the basis of each of the qubits affected by a σₓ or σ_{y} into the σ_{z} basis (there are only two such qubits for each rotation, which is independent of n) followed by rotation around the z-axis while accounting for parity. Therefore, the two-qubit rotations are independent of n and the overall depth of Eq. (33) is [symbol] (n).

With the boundary operator performed analytically there can be a saving in the number of shots needed compared to the Trotterized version. In the Trotterized version, Δ (the Laplacian of the restricted boundary operator) is implemented via Taylor expansion of the Trotterized evolution of exp(iBt) for small t and solving for Δ. In order to account for Trotterization error, [symbol] (t²)<∈. Therefore [symbol] (t)<\sqrt{∈}. In order to account for the Taylor-expansion-and-solve-for-B error, the intermediate expectation calculation should be known to within ∈ₙ [symbol] (t²). Therefore, [symbol] (t)<∈ₙ [symbol] (t²) and 1/∈<n [symbol] (t). Therefore, 1/(∈ₙ)< [symbol] (t)<\sqrt{∈}. This may show that not all ∈ can be achieved.

Next, consider, for achievable e, the number of samples needed to overcome shot-noise

$$( {ϵ}_{shot} ∼ \frac{1}{\sqrt{N}} ) .$$

The measurement expectation should be known to within ∈ₛₕₒₜ<∈ [symbol] (t²)<∈². Therefore the number of samples needed is

$$N > 𝒪 ( \frac{1}{{ϵ}^{4}} ) .$$

In contrast, since there is no Trotterization and Taylor expansion error for the analytic circuit, the number of samples needed can be

$$N > 𝒪 ( \frac{1}{{ϵ}^{2}} ) ,$$

which is a quadratic saving (and more for higher moments).

In one or more embodiments, a short-depth ( [symbol] (n)) quantum circuit for the exact, analytical implementation of the full Hermitian boundary operator on a gate-based quantum computer can be provided. The quantum circuit can provide for an improvement over a Trotterized implementation, which can result in at least quadratic savings in the number of shots. A formal proof is described above for the proposition that the boundary operator can be written as a sum of fermionic creation and annihilation operators. This connection between algebraic geometry and fermionic operators can potentially be explored for applications in other areas. The fermionic representation together with the property of pairwise Pauli anticommutation permits implementation via a short-depth circuit implementing a cascade of two-qubit rotations. With such a short-depth circuit for the full boundary operator, additional quantum implementations of many algorithms that have the boundary operator as a component, e.g., including in the fields of differential equations and machine learning, can be contemplated.

By way of example, the following illustrates the formulae described above with the explicit example of n=3. There are three vertices in the example here, which can be called, ν_{0,1,2}. The following then uses binary degree-lexicographic representation of the 8 simplices constructible from these vertices as follows:

| Dimension | Binary | Simplex |
|---|---|---|
| — | 000 | ø |
| 0 | 001 | v₀ |
| | 010 | v₁ |
| | 100 | v₂ |
| 1 | 011 | line(v₀, v₁) |
| | 101 | line(v₀, v₂) |
| | 110 | line(v₁, v₂) |
| 2 | 111 | triangle(v₀, v₁, v₂) |

A few of the boundary operators as defined above can be checked as follows. Consider ∂₁⁽³⁾, which should take a line to its boundary endpoints, with sign. Take |s₁ [symbol] =011, there are only 2 terms contribution since the Kronecker-delta picks out νᵢ and ν₀, i.e., i=0,1

a.∂₁⁽³⁾|s₁ [symbol] =(−1)^{Σ}^{ⱼ₌₁}^{²}^{s}^{₁}^{(j)}ν₀+(−1)^{Σ}^{ⱼ₌₂}^{²}^{s}^{₁}^{(j)}ν₁=(−1)¹⁺²ν₀+(−1)⁰ν₁=ν₁−ν₀. (36)

Next, take |s₂ [symbol] =111 and act upon it with ∂₂⁽³⁾, whereupon all 3 terms in the sum contribute:

b.∂₂⁽³⁾|s₂ [symbol] =(−1)^{Σ}^{ⱼ₌₁}^{²}^{s}^{₂₍ⱼ₎}ν₀+(−1)^{Σ}^{ⱼ₌₂}^{²}^{s}^{₂₍ⱼ₎}ν₁+(−1)^{Σ}^{ⱼ₌₃}^{²}^{s}^{₂₍ⱼ₎}ν₂(−1)¹⁺¹ν₀+(−1)¹ν₁+(−1)⁰ν₂=ν₀−ν₁+ν₂, (37)

which says that that the boundary of the triangle are the 3 (signed) edges.

The Boundary Operator ∂⁽ⁿ⁾

The following shows the boundary operator ∂⁽ⁿ⁾, constructed from the pieces ∂ₖ⁽ⁿ⁾ given in Eq. (6), explicitly. The initial cases are simply:

$${\partial }^{( 1 )} = ( \begin{matrix}0 & 1 \\ 0 & 0\end{matrix} ) , \qquad ( 38 )$$

$${\partial }^{( 2 )} = {a}_{0} + {a}_{1} = {σ}_{z} ⊗ {Q}^{+} + {Q}^{+} ⊗ I = ( \begin{matrix}0 & 1 & 0 & 0 \\ 0 & 0 & 0 & 0 \\ 0 & 0 & 0 & - 1 \\ 0 & 0 & 0 & 0\end{matrix} ) + ( \begin{matrix}0 & 0 & 1 & 0 \\ 0 & 0 & 0 & 1 \\ 0 & 0 & 0 & 0 \\ 0 & 0 & 0 & 0\end{matrix} ) = ( \begin{matrix}0 & 1 & 1 & 0 \\ 0 & 0 & 0 & 1 \\ 0 & 0 & 0 & - 1 \\ 0 & 0 & 0 & 0\end{matrix} ) ,$$

$${\partial }^{( 3 )} = {a}_{0} + {a}_{1} + {a}_{2} = {σ}_{z} ⊗ {σ}_{z} ⊗ {Q}^{+} + {σ}_{z} ⊗ {Q}^{+} ⊗ I + {Q}^{+} ⊗ I ⊗ I = ( \begin{matrix}0 & 1 & 0 & 0 & 0 & 0 & 0 & 0 \\ 0 & 0 & 0 & 0 & 0 & 0 & 0 & 0 \\ 0 & 0 & 0 & - 1 & 0 & 0 & 0 & 0 \\ 0 & 0 & 0 & 0 & 0 & 0 & 0 & 0 \\ 0 & 0 & 0 & 0 & 0 & - 1 & 0 & 0 \\ 0 & 0 & 0 & 0 & 0 & 0 & 0 & 0 \\ 0 & 0 & 0 & 0 & 0 & 0 & 0 & 1 \\ 0 & 0 & 0 & 0 & 0 & 0 & 0 & 0\end{matrix} ) + ( \begin{matrix}0 & 0 & 1 & 0 & 0 & 0 & 0 & 0 \\ 0 & 0 & 0 & 1 & 0 & 0 & 0 & 0 \\ 0 & 0 & 0 & 0 & 0 & 0 & 0 & 0 \\ 0 & 0 & 0 & 0 & 0 & 0 & 0 & 0 \\ 0 & 0 & 0 & 0 & 0 & 0 & - 1 & 0 \\ 0 & 0 & 0 & 0 & 0 & 0 & 0 & - 1 \\ 0 & 0 & 0 & 0 & 0 & 0 & 0 & 0 \\ 0 & 0 & 0 & 0 & 0 & 0 & 0 & 0\end{matrix} ) + ( \begin{matrix}0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1 \\ 0 & 0 & 0 & 0 & 0 & 0 & 0 & 0 \\ 0 & 0 & 0 & 0 & 0 & 0 & 0 & 0 \\ 0 & 0 & 0 & 0 & 0 & 0 & 0 & 0 \\ 0 & 0 & 0 & 0 & 0 & 0 & 0 & 0\end{matrix} ) = ( \begin{matrix}0 & 1 & 1 & 0 & 1 & 0 & 0 & 0 \\ 0 & 0 & 0 & 1 & 0 & 1 & 0 & 0 \\ 0 & 0 & 0 & - 1 & 0 & 0 & 1 & 0 \\ 0 & 0 & 0 & 0 & 0 & 0 & 0 & 1 \\ 0 & 0 & 0 & 0 & 0 & - 1 & - 1 & 0 \\ 0 & 0 & 0 & 0 & 0 & 0 & 0 & - 1 \\ 0 & 0 & 0 & 0 & 0 & 0 & 0 & 1 \\ 0 & 0 & 0 & 0 & 0 & 0 & 0 & 0\end{matrix} ) .$$

Nilpotency

The following checks that the boundary operator is nilpotent, as is required from homology:

Lemma 2. The boundary operator satisfies ∂⁽ⁿ⁾·∂⁽ⁿ⁾=0.

Proof. A proof can proceed by induction. Immediately, one checks that (∂⁽¹⁾)²=(∂₍₂₎)²=(∂⁽³⁾)²=0 where 0 is the 2ⁿ×2ⁿ matrix of zeros; thus, the initial terms check out. Next, assume that (∂⁽ⁿ⁾)²=0 as the induction hypothesis. Now, there is (the third line uses the so-called mixed product rule for Kronecker and dot products):

$${( {\partial }^{( n + 1 )} )}^{2} = {( {\partial }^{( n )} ⊗ I + {σ}_{z}^{⊗ n} ⊗ {Q}^{+} )}^{2} = {( {\partial }^{( n )} ⊗ I )}^{2} + {( {σ}_{z}^{⊗ n} ⊗ {Q}^{+} )}^{2} + ( {\partial }^{( n )} ⊗ I ) \cdot ( {σ}_{z}^{⊗ n} ⊗ {Q}^{+} ) + ( {σ}_{z}^{⊗ n} ⊗ {Q}^{+} ) \cdot ( {\partial }^{( n )} ⊗ I ) = {( {\partial }^{( n )} )}^{2} ⊗ {I}^{2} + {( {σ}_{z}^{⊗ n} )}^{2} ⊗ {( {Q}^{+} )}^{2} + ( {\partial }^{( n )} \cdot {σ}_{z}^{⊗ n} ) ⊗ ( I \cdot {Q}^{+} ) + ( {σ}_{z}^{⊗ n} \cdot {\partial }^{( n )} ) ⊗ ( {Q}^{+} \cdot I ) [ since ( A ⊗ B ) \cdot ( C ⊗ D ) = ( AC ) ⊗ ( BD ) , the mixed - product identity ] = 0 + 0 + ( {σ}_{z}^{⊗ n} \cdot {\partial }^{( n )} + {\partial }^{( n )} \cdot {σ}_{z}^{⊗ n} ) ⊗ v [ since {( {\partial }^{( n )} )}^{2} = {( {Q}^{+} )}^{2} = 0 ] . \qquad ( 39 )$$

Thus it suffices to prove the anticommutation

a. {σ_{z}^{⊗n},∂⁽ⁿ⁾}=σ_{z}^{⊗n}·∂⁽ⁿ⁾+∂⁽ⁿ⁾·σ_{z}^{⊗n}=0 (40)

To see this, another, separate induction can be set up. Clearly, the initial terms check out: {∂⁽¹⁾, σ_{z}}={∂⁽²⁾, σ_{z}^{⊗n}}=0. Now, let the induction hypothesis be:

$$\{ {σ}_{z}^{⊗ n} , {\partial }^{( n )} \} = 0 , and consider \qquad ( 41 )$$

$$\{ {σ}_{z}^{⊗ ( n + 1 )} , {\partial }^{( n )} \} = \{ {σ}_{z}^{⊗ ( n + 1 )} , {\partial }^{( n )} ⊗ I + {σ}_{z}^{⊗ n} ⊗ {Q}^{+} \} = \{ {σ}_{z}^{⊗ n} ⊗ {σ}_{z} , {\partial }^{( n )} ⊗ I + {σ}_{z}^{⊗ n} ⊗ {Q}^{+} \} = \{ {σ}_{z}^{⊗ n} , {\partial }^{( n )} \} ⊗ ( {σ}_{z} \cdot I ) + ( {σ}_{z}^{⊗ n} \cdot {σ}_{z}^{⊗ n} ) ⊗ \{ {σ}_{z} , {Q}^{+} \} . \qquad ( 42 )$$

Now, the first term vanishes by induction hypothesis, and the second term also vanishes since {σ_{z}, Q⁺}={∂⁽¹⁾, σ_{z}}=0, the initial term.

Hamiltonian

The following can also check the explicit form of the Hamiltonian exp(iB⁽ⁿ⁾t)=exp(i(∂⁽ⁿ⁾+(∂^{(l)})^{†})) against Eq. (34).
n=1:
Here, there is

$${B}^{( 1 )} = {\partial }^{( 1 )} + {( {\partial }^{( 1 )} )}^{†} = ( \begin{matrix}0 & 1 \\ 1 & 0\end{matrix} ) , so that \qquad ( 43 )$$

$$exp ( {iB}^{( 1 )} t ) = ( \begin{matrix}cos ( t ) & - i sin ( t ) \\ - i sin ( t ) & cos ( t )\end{matrix} ) .$$

On the right hand side of the theorem, there is

$$R = {R}_{0} {R}_{1} , where {R}_{0} = {I}_{2} and {R}_{1} = exp ( \frac{1}{2} {Q}_{0} {Q}_{1} a tan 2 ( 0 , 1 ) ) = {I}_{2} .$$

Hence, the right hand side is just exp(−iX₀t)=exp(−1σₓt). Recalling that for integer n,

$${σ}_{x}^{2 n - 1} = {σ}_{x} = ( \begin{matrix}0 & 1 \\ 1 & 0\end{matrix} ) , \qquad ( 44 )$$

$${σ}_{x}^{2 n} = {I}_{2} ,$$

there is equality.
n=2:
From the forms of ∂⁽ⁿ⁾ it can be found:

$$exp ( {iB}^{( 2 )} t ) = ( \begin{matrix}cos ( \sqrt{2} t ) & - \frac{i sin ( \sqrt{2} t )}{\sqrt{2}} & - \frac{i sin ( \sqrt{2} t )}{\sqrt{2}} & 0 \\ - \frac{i sin ( \sqrt{2} t )}{\sqrt{2}} & cos ( \sqrt{2} t ) & 0 & - \frac{i sin ( \sqrt{2} t )}{\sqrt{2}} \\ - \frac{i sin ( \sqrt{2} t )}{\sqrt{2}} & 0 & cos ( \sqrt{2} t ) & \frac{i sin ( \sqrt{2} t )}{\sqrt{2}} \\ 0 & - \frac{i sin ( \sqrt{2} t )}{\sqrt{2}} & \frac{i sin ( \sqrt{2} t )}{\sqrt{2}} & cos ( \sqrt{2} t )\end{matrix} ) . \qquad ( 45 )$$

This explicit matrix can be cross-checked against Eq. (34). There is, from ∂⁽²⁾, that

$$R = {R}_{1} = exp ( \frac{1}{2} {Q}_{0} {Q}_{1} a tan 2 ( \sqrt{2 - 1} , 1 ) ) . Thus ,$$

$$( 46 )$$

$${R}_{1} = exp ( \frac{π}{8} ( {a}_{0} + {a}_{0}^{†} ) ( {a}_{1} + {a}_{1}^{†} ) ) = ( \begin{matrix}cos ( \frac{π}{8} ) & 0 & 0 & sin ( \frac{π}{8} ) \\ 0 & cos ( \frac{π}{8} ) & sin ( \frac{π}{8} ) & 0 \\ 0 & - sin ( \frac{π}{8} ) & cos ( \frac{π}{8} ) & 0 \\ - sin ( \frac{π}{8} ) & 0 & 0 & cos ( \frac{π}{8} )\end{matrix} ) .$$

$$Hence ,$$

$$( 47 )$$

$${R}^{†} exp ( - i \sqrt{2} ( {a}_{0} + {a}_{0}^{†} ) t ) R = ( \begin{matrix}cos ( \sqrt{2} t ) & - \frac{i sin ( \sqrt{2} t )}{\sqrt{2}} & - \frac{i sin ( \sqrt{2} t )}{\sqrt{2}} & 0 \\ - \frac{i sin ( \sqrt{2} t )}{\sqrt{2}} & cos ( \sqrt{2} t ) & 0 & - \frac{i sin ( \sqrt{2} t )}{\sqrt{2}} \\ - \frac{i sin ( \sqrt{2} t )}{\sqrt{2}} & 0 & cos ( \sqrt{2} t ) & \frac{i sin ( \sqrt{2} t )}{\sqrt{2}} \\ 0 & - \frac{i sin ( \sqrt{2} t )}{\sqrt{2}} & \frac{i sin ( \sqrt{2} t )}{\sqrt{2}} & cos ( \sqrt{2} t )\end{matrix} ) .$$

and there is perfect agreement of Eq. (45) and Eq. (47).

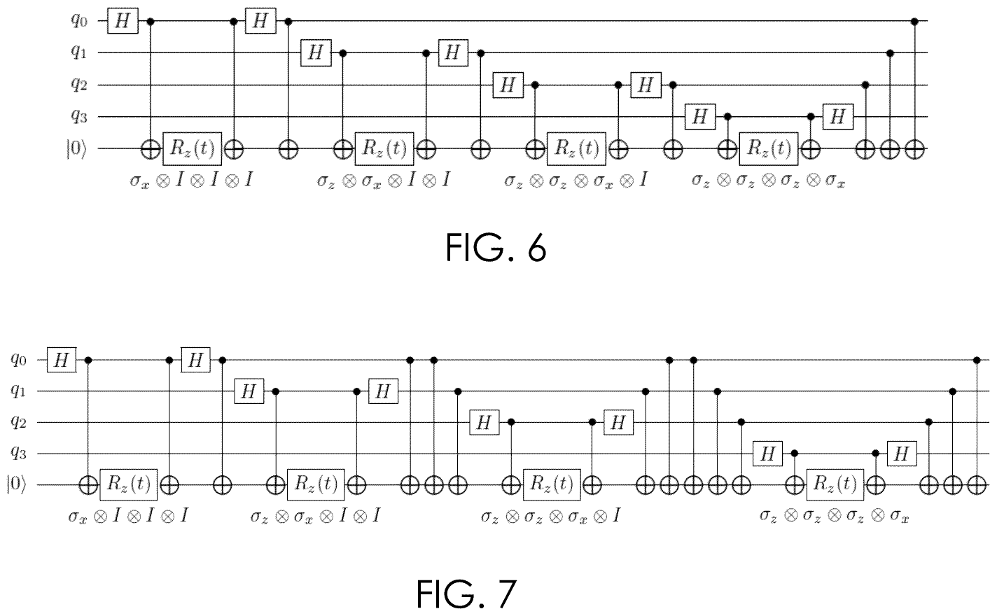

As discussed above, a quantum circuit can implement or simulate a boundary operator. A quantum circuit can include a sequence of quantum gates and initialization of qubits to known values, and may also include measurements. FIG. 6 is a diagram illustrating a quantum circuit for a boundary operator in another embodiment. The quantum circuit in an embodiment can be constructed with CNOT, Hadamard (H), and rotation gates, e.g., R_{z}(t) gates. Using gate cancellations related to commuting Pauli subterms, in an embodiment, the quantum circuit can achieve O(n) gates, e.g., 2(2n−1) CNOT gates, 2n Hadamard gates, and n rotation gates. The depth of this circuit can be 4n, and therefore it is NISQ implementable. By way of example, the quantum circuit implements a specific example of a quantum circuit generally presented by Eq. Eq. (6).

As described above, the boundary operator B can be represented efficiently as a sum of Pauli operators. For instance, as described above with reference to Eq. (6), the matrix a (e.g., also known as the single spin annihilation operator from second quantization quantum mechanics) can be defined as

$$a = \frac{( {σ}_{x} + i {σ}_{y} )}{2} = ( \begin{matrix}0 & 1 \\ 0 & 0\end{matrix} ) ,$$

where α is written in terms of the Pauli operators σₓ and σ_{y}. This α can be considered as removing a specific vertext out of a simplex. Note, by inspection or by recognizing the coefficient of σ_{y} is imaginary, that both a and the boundary operator below are not Hermitian. Similar to Eq. (6) above, the full boundary map operator ∂=⊕ₖ∂ₖ of all possible simplices can be written in the following manner,

$$\begin{matrix}\partial = a ⊗ I ⊗ I ⊗ … I \\ + {σ}_{Z} ⊗ a ⊗ I ⊗ … I \\ + {σ}_{Z} ⊗ {σ}_{Z} ⊗ a ⊗ … I \\ ⋮ \\ + {σ}_{Z} ⊗ {σ}_{Z} ⊗ {σ}_{Z} ⊗ … ⊗ a \\ = {\sum }_{i = 0}^{n - 1} {a}_{i} ,\end{matrix}$$

where the αᵢ are the Jordan-Wigner Pauli embeddings corresponding to the n-spin fermionic annihilation operators.

The ⊗ is the tensor product (as many as qubits, n), and α is applied consecutively to each qubit, preceded by σ_{z} (also referred to as Z matrices). The identity matrices, leave other vertices in-place, if they are there. The tensor of Z matrices before the α matrix in each term achieves the parity calculation, which keeps track of the sign of the boundary simplex. There are n terms. The boundary matrix applies to a vector of size: 2ⁿ (2 to the power of n, also denoted as 2\hat{ }n). For example, this vector encodes the simplices (points, edges, faces, . . . ) in binary characteristic form (0 for absent, 1 for present). The Hermitian full Boundary map matrix can be given as B=∂^{†}+∂=Σi=0ⁿ⁻¹αᵢ+aᵢ^{†}.

There can be n single qubit operations in the tensor product in each of the above terms, one for each vertex in the simplicial complex. The α term “removes a vertex” from a simplex and the instances of σ_{z} provide the correct sign in the oriented sum by accumulating as many instances of −1 as there are vertices present to the left of the vertex being removed (also known as anti-symmetrizing the wave function).

This non-Hermitian operator can be transformed into an associated Hermitian operator by adding its complex conjugate as

a.B=∂^{†}+∂=Σᵢ₌₀ⁿ⁻¹αᵢ+αᵢ^{†}.

Since the σ_{y} terms cancel out, the matrix B only has σₓ and σ_{z} terms. B can be expressed as a sum of polynomially-many Pauli terms, and e^{iB} can be simulated efficiently, e.g., using the Trotter-Suzuki formula. The structure of the quantum circuit can further be reduced with gate cancellations to achieve a depth complexity of O(n). That is, the number of gates implemented on the quantum circuit can be linearly related, e.g., by some constant value, to n, the number of qubits representing the vertices in a simplicial complex.

The following describes details on the simulation of B in another embodiment, for example, as shown in FIG. 6 and FIG. 7. In this embodiment also, a representation for the boundary operator B can implemented as a sum of Pauli operators. For a quantum implementation, a unitary U_{B}(t)=e^{-iBt} for some t can be constructed. For instance, to do so, the Trotter-Suzuki formula can be used: Supposing an n-qubit Hamiltonian is written as A=Σⱼ₌₁ⁿ Aⱼ, then there can be

b.e^{-iΣ}^{ⱼ₌₁}^{ⁿ}^{A}^{ⱼ}^{t}=Πⱼ₌₁¹e⁻ⁱ^{ⱼ}^{t}+O(n²t²),

where the error in this approximation is negligible when t [symbol] 1.

Each Aⱼ are Pauli terms {σₓ, σ_{y}, σ_{z}, σᵢ}^{⊗n}. Pauli terms commute with each other. Hence, by permuting blocks to align the terms that commute, several gates can be cancelled in order to reduce the size (both gate and depth complexity) of the circuit.

In an embodiment, the Pauli terms can be mapped to quantum circuits using diagonalization and unitary evolution. The Pauli terms {σ_{z}, σᵢ}^{⊗n} are already diagonal, and thus there can be e^{iσ}^{ᵢ}^{t}=e^{it}I and

$${e}^{i {σ}_{z} t} = [ \begin{matrix}{e}^{it} & 0 \\ 0 & {e}^{- it}\end{matrix} ] \text{=:} {R}_{Z} ( t ) .$$

Using diagonalization, the Pauli σₓ=Hσ_{z}H^{T}, where

$$H = \frac{1}{\sqrt{2}} [ \begin{matrix}1 & 1 \\ 1 & - 1\end{matrix} ]$$

is the Hadamard matrix, and e^{-iσ}^{ₓ}^{t}=He^{iσ}^{_{z}}^{t}H^{T}=HR_{z}(t)H^{T}.

Next, for the boundary operator B=∂+∂^{†}, there can be

$$\begin{matrix}B = {σ}_{x} ⊗ I ⊗ I ⊗ … I \\ + {σ}_{Z} ⊗ {σ}_{x} ⊗ l ⊗ … I \\ ⋮ \\ + {σ}_{Z} ⊗ {σ}_{Z} ⊗ {σ}_{Z} ⊗ … ⊗ {σ}_{x} ,\end{matrix}$$

since α+α^{†}=σₓ. Therefore, e^{iBt} can be simulated using a quantum circuit with CNOT, Hadamard H, and rotation R_{z}(t) gates.

For example, supposing n=4, the basic circuit (with one ancillary qubit) can be obtained for B using the above diagonalization. An embodiment of this basic circuit is shown in FIG. 7. In this implementation, the circuit has O(n²) gates (i.e., n(n+1) CNOT gates, n rotation R_{z}(t) gates, and 2n Hadamard H gates) with depth O(n²). This circuit can be simplified by identifying sub-terms that commute and then using gate cancellations. Since the sub-terms {σ_{z}}^{⊗r} for different r values between the terms in B commute, a number of CNOT gates can be cancelled (because they are redundant). FIG. 6 shows the simplified circuit. The simplified circuit shown in FIG. 6 has O(n) gates, simplified using gate cancellations related to commuting Pauli subterms. The simplified circuit for simulating e^{iBt} now has O(n) gates, i.e., 2(2n−1) CNOT gates, 2n Hadamard gates, and n rotation gates. The depth of this circuit is 4n.

Referring to FIG. 6, a quantum circuit is shown that is a decomposition of a boundary map. The circuit can include n qubits and an ancillary qubit (an extra qubit, also referred to an an ancilla bit). The n qubits can correspond to n vertices of a simplex and via superposition of the entire simplicial complex, on which the boundary operator or map acts. For instance, through superposition, n vertices can be “reused” by each simplex in the simplicial complex. FIG. 6 shows a specific example where n is 4. Each vertex can be assigned a qubit of n qubits in the circuit.

Pauli operators or matrices can represent quantum gates. For example, there is a Pauli gate or matrix for each axis in space (X, Y and Z) or bloch sphere. The X-gate is represented by the Pauli-X (or σₓ) matrix:

$$[ \begin{matrix}0 & 1 \\ 1 & 0\end{matrix} ] .$$

A Pauli gate acts on one qubit at a time. The Pauli X-gate corresponds to a classical NOT gate. For example, the X-gate can be referred to as the quantum NOT gate. The X-gate generally turns the spin-up state |0> of an electron into a spin-down state |1> and vice-versa.

Likewise, the Y (also referred to as σ_{y}) and Z (also referred to as σ_{z}) Pauli matrices act as the Y-gate and the Z-gate: The following shows the Pauli Y and Z gates expressed in matrix forms.

$$Y : [ \begin{matrix}0 & - i \\ i & 0\end{matrix} ]$$

$$Z : [ \begin{matrix}1 & 0 \\ 0 & - 1\end{matrix} ]$$

Generally, the Pauli X gate action can be considered a rotation by π (pi) radians (180 degrees) around the x-axis of the Bloch sphere, and can result in the bit flip; the Pauli Z gate action can be considered a rotation by π radians around the z-axis of the Bloch sphere, and can result in the phase flip; and the Pauli Y gate action can be considered a rotation by π radians around the y-axis of the Bloch sphere, and can result in both the bit flip and the phase flip simultaneously. Pauli operators have properties such that two Pauli operators commute only if they are identical or one of them is the identity operator or matrix, otherwise they anticommute. For example, aᵢaⱼ=I, if i=j; and aᵢaⱼ=0, if i≠j; where i and j are x, y or z of the Pauli operators, and I is the identify matrix.

Generally, controlled gates act on two or more qubits, where one or more qubits act as a control for some specified operation. The controlled NOT gate (or CNOT) can act on 2 qubits, and perform the NOT operation on the second qubit (target) if the first qubit (control) is |1 [symbol] , and if the first qubit is |0 [symbol] , leave the second qubit unchanged. The solid circle or dot represents a control bit. If the control bit is |1 [symbol] (e.g., from the first qubit), the CNOT gate acts on (performs NOT operation on) the second qubit (e.g., the ancillary qubit), otherwise, the second qubit is left unchanged. The CNOT gate is annotated with ‘+’ within a circle. The Hadamard gate or H-gate (annotated as ‘H’ within a box) creates superpositions of vectors. For example, the Hadamard gate turns vector

$$\vert 0 〉 to \frac{1}{\sqrt{2}} ( \vert 0 〉 + \vert 1 〉 ) ;$$

turns vectors

$$\vert 1 〉 to \frac{1}{\sqrt{2}} ( \vert 0 〉 - \vert 1 〉 ) .$$

H-gate rotates the qubit state by π (pi) radians (180 degrees) about an axis diagonal in the x-z plane of the Bloch sphere. This is equivalent to an X-gate followed by a π/2 rotation about the y-axis. The Rotation R_{z} gate rotates or flips the qubit around the z-axis of the bloch sphere.

The quantum circuit shown in FIG. 6 has five quantum bits or qubits. The four qubits correspond to n (e.g., 4) vertices that form a simplicial complex. The circuit can receive n qubits encoded with information. The fifth qubit is an ancillary qubit set to |0 [symbol] . The Hadamard gate is a single qubit gate and applies to only one qubit. The quantum circuit shown includes two types of single qubit gates, the Hadamard gate and Rotation R_{z} gate. There is one type of two qubit gates that connects two qubits, which is the CNOT-gate. For example, a CNOT-gate connects the ancillary qubit to the other qubits that are assigned to the n vertices.

In an aspect, the number of non-parallel gates, i.e., those that run on their own time slice, is called depth of gate or gate depth. For example, there can be ten gates total in a quantum circuit, but its gate depth can be five, if some of the gates can be run in parallel, that is, at the same time slice. One or more quantum circuits disclosed herein is able to use O(n) gates and depth, where n corresponds to the number of vertices (or nodes). A practical example of a vertex can be a data point that represents an object with one or more attributes. Another example can be a patient having one or more attributes, for example, of a health or medical database. As more vertices are added, more qubits (e.g., horizontal line in FIG. 6) can be added. For example, there can be a qubit per vertex or node. That is, as n grows, the number of qubits grows, and the boundary operator can become larger. O(n) or order n shows that the number of gates used in the quantum circuit grows linearly by some constant value as the number of vertices (qubits) grows. The gate depth also increases linearly with respect to the number of vertices, i.e., the gate depth of O(n) can also be achieved. Hence, the quantum circuit can achieve short gate and short depth. O(n) gate and O(n) depth provides an improvement over the existing quantum circuits that may implement a boundary operator, which have O(n²) gate and depth.

Referring to FIG. 6, generally, the quantum circuit includes and extra qubit or ancillary qubit (ancilla bit), on which CNOT-gate is performed. For example, if there are four vertices, one extra qubit is included and the circuit operates by performing a CNOT into that extra qubit, e.g., based on the values of the four qubits that are the vertices. In an embodiment, the circuit controls into one qubit, and hence the underlying quantum computer on which the circuit can be implemented, only needs to have a connectivity between other qubits and this one qubit. For instance, the control bit associated with q₀ is connected to the ancilla bit, where based on the control bit, CNOT can be performed on the ancilla bit; the control bit associated with q₁ is connected to the ancilla bit, where based on the control bit, CNOT can be performed on the ancilla bit; the control bit associated with q₂ is connected to the ancilla bit, where based on the control bit, CNOT can be performed on the ancilla bit; Hadamard gate is acted on q₃ and the control bit associated with q₃ is connected to the ancilla bit, where based on the control bit of associated with q₃, CNOT can be performed on the ancilla bit; a rotation is performed on the ancilla bit; and so on (reading the circuit from left to right). Thus, in an embodiment, only one qubit needs to be highly connected. For instance, there is no CNOTs between the four qubits (q₀, q₁, q₂, q₃).

As described above, the generic template for a quantum circuit can be given by Eq. (33), and also by Eq. (6). Those formulae decompose the boundary operator or represent the boundary operator in terms of simple objects which can be represented in quantum computing. For instance, a 2×2 matrix form can be represented using quantum gates such as the four basic gates, which are Pauli gates based on Pauli operators. This 2×2 form can be combined with other set of such 2×2 matrices to build a 2ⁿ (also expressed as 2\hat{ }n) matrix. For example, if there are n points or vertices, the boundary operator can be a 2ⁿ matrix. This 2ⁿ matrix can be constructed using the 2×2 building blocks. For any given n, using this building block, 2ⁿ boundary operator can be constructed. In an embodiment, a quantum circuit provides an actual representation of such matrix on a quantum computer.

A boundary map or operator, which can be expressed as a 2ⁿ×2ⁿ matrix, can represent a graph that defines connections between two or more points, nodes or vertices. For instance, where the data represents a simplicial complex, the subscript k in the term ∂ₖ, represents a simplex dimension. For example, subscript of 1 (e.g., ∂₁) indicates a connection between two points (forming a line); subscript 2 (e.g., ∂₂) indicates connections between three points (forming a triangle), e.g., how many triangles are connected among one another; and so on. The sum of all the connections can be 2ⁿ (also expressed as 2\hat{ }n). In an embodiment, the boundary map can be decomposed into components that can be mapped to quantum primitives, e.g., Pauli operators. For example, a quantum circuit implementation can construct a boundary map or operator, which can be an exponentially large matrix, using O(n) gates and depth on the quantum computer. In an embodiment, only one qubit needs to be well connected to other qubits in the quantum circuit. Such boundary map can have many different applications. As the number of qubits increases, the circuit can be scaled to include additional set of gates, e.g., 3 CNOT gates, 2 H gates and a Rz gate, which connect the ancilla gate and an additional qubit. For instance, each set of operators correspond to a Pauli operator or Pauli string, which is quantum circuit mapped. For example, referring to Eq. (6), each αᵢ in Σᵢ₌₀ⁿ⁻1 αᵢ can be a Pauli operator or Pauli string. Further, considering the pairwise anticommute properties of the Pauli operator, some gates can be cancelled to reduce the overall gate depth. Connecting the individual qubits and using rotation operations systematically translates the initial state to quantum states that construct the boundary operator on a quantum computer.

So for example, the quantum circuit shown in FIG. 6 and/or FIG. 7 can include at least n input qubit registers (or qubits); an ancilla qubit register (or qubits); and n sets of third quantum gates, wherein a set of third quantum gates is configured to perform tensor product of Pauli X matrix and i number of Pauli Z matrices, for qubit register i, where i can be 0 to n−1. For example, each set in the n sets of third quantum gates can be configured thusly.

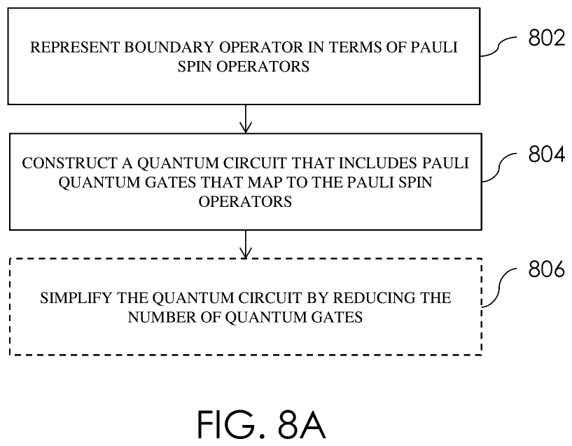

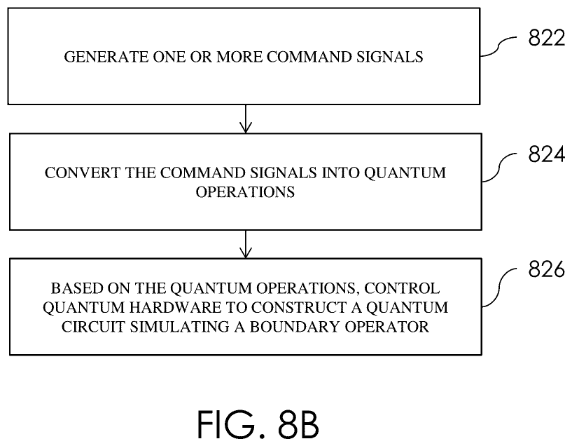

FIG. 8A is a flow diagram illustrating a method or process of providing or building a quantum circuit that can simulate a boundary operator in an embodiment. The example process shown may include one or more operations, actions, or functions as illustrated by one or more of blocks. Although illustrated as discrete blocks, various blocks can be divided into additional blocks, combined into fewer blocks, eliminated, performed in different order, or performed in parallel, depending on the desired implementation.

At 802, the method can include representing a boundary operator that maps boundaries of a given graph having at least nodes and edges in terms of Pauli spin operators, the boundary operator decomposed as a sum of the Pauli spin operators. In an embodiment, a boundary operator can be represented that maps a given graph with nodes and edges to its boundaries. For example, in an embodiment, the method can include representing a boundary operator that maps simplices of orders, e.g., of all orders, in a given simplicial complex in terms of Pauli spin operators, the boundary operator decomposed as a sum of the Pauli spin operators, for example, for example, as described above. At 804, the method can include constructing on or for a quantum computer, a quantum circuit that includes Pauli quantum gates that map to the Pauli spin operators, for example, as described above. In an embodiment, the Pauli spin operators are mapped into fermionic creation and annihilation operators. In an embodiment, the quantum circuit operates on n qubits corresponding to n vertices in the given simplicial complex, and an ancillar qubit. In an embodiment, the quantum circuit operates on two qubits of the n qubits and an ancilla bit at a time. In another embodiment, the connectivity in the quantum circuit occurs only between the ancilla qubit and one the n qubits at a time.

In an embodiment, at 806, the method may also include simplifying the quantum circuit, e.g., reducing the number of Pauli quantum gates in the quantum circuit based on anticommutation property associated with the Pauli spin operators. In an embodiment, consecutive or series of single qubit gates can be combined into a unitary operator.

FIG. 8B is another flow diagram illustrating a method or process of providing or building a quantum circuit that can simulate a boundary operator in an embodiment. The example process shown may include one or more operations, actions, or functions as illustrated by one or more of blocks. Although illustrated as discrete blocks, various blocks can be divided into additional blocks, combined into fewer blocks, eliminated, performed in different order, or performed in parallel, depending on the desired implementation.

At 822, the method can include a controller such as a controller of a quantum system generating one or more command signals. In an embodiment, for example, the command signals indicate what operations are to be performed on qubits of quantum hardware. At 824, the method can also include an interface of the quantum system converting the command signals into quantum operations. For instance, the interface can convert the command signals into signals that can drive or manipulate qubits, for example, to perform operations on the qubits. At 826, the method can include the interface of the quantum system, based on the quantum operations, controlling quantum hardware of the quantum system to construct a quantum circuit including at least Pauli quantum gates. For example, control signals (e.g., quantum operations) applied to or routed to one or more qubits control gate operates that construct the quantum circuit. The quantum circuit can be configured to simulate a boundary operator that creates a mapping of boundaries of a given graph having at least nodes and edges. In an embodiment, the quantum circuit can have linear depth relative to the number of nodes in the given graph.

In an embodiment, a boundary operator can be represented that maps a given graph with nodes and edges to its boundaries. In an embodiment, a boundary operator that maps boundaries of a given graph having at least nodes and edges can be represented in terms of Pauli spin operators, the boundary operator decomposed as a sum of the Pauli spin operators. For example, in an embodiment, a boundary operator can map simplices of orders, e.g., of all orders, in a given simplicial complex in terms of Pauli spin operators, where the boundary operator can be decomposed as a sum of the Pauli spin operators. In an embodiment, the Pauli spin operators are mapped into fermionic creation and annihilation operators. In an embodiment, the quantum circuit operates on n qubits corresponding to n vertices in the given simplicial complex, and an ancillar qubit. In an embodiment, the quantum circuit operates on two qubits of the n qubits and an ancilla bit at a time. In another embodiment, the connectivity in the quantum circuit occurs only between the ancilla qubit and one the n qubits at a time.

In an embodiment, the quantum circuit can be a simplified quantum circuit, e.g., the number of Pauli quantum gates in the quantum circuit being reduced based on anticommutation property associated with the Pauli spin operators. In an embodiment, consecutive or series of single qubit gates can be combined into a unitary operator to simplify the quantum circuit.

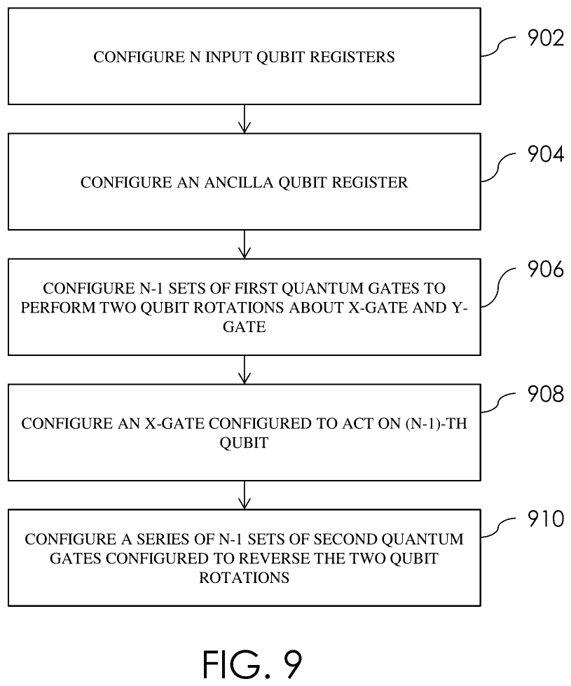

FIG. 9 is another flow diagram illustrating a method of constructing a quantum circuit, which can simulate a boundary operator in an embodiment. In an embodiment, the boundary operator can map a given simplicial complex to its boundaries. In another embodiment, the boundary operator can map a given graph with nodes and edges to their boundaries. At 902, n input qubit registers (or qubits) can be configured or allocated, for example, on a quantum computer. At 904, an ancilla qubit register (or qubits) can be configured. At 906, n−1 sets of first quantum gates can be configured to perform two qubit Pauli Xᵢ₋₁ and Yᵢ rotations applied to the (i−1)-th and i-th qubits, where i=1 to n−1. At 908, an X-gate can be configured to act on (n−1)-th qubit, for example, on quantum state of the (n−1)-th qubit subsequent to a cascade of two qubit rotations performed by the n−1 sets of first quantum gates. At 910, a series of n−1 sets of second quantum gates can be configured to reverse the two qubit rotations performed by the n−1 sets of first quantum gates.

FIG. 10 illustrates a schematic of an example computer or processing system 11 that may implement a boundary operator quantum circuit in an embodiment. The computer system 11 is an example of a suitable processing system and is not intended to suggest any limitation as to the scope of use or functionality of embodiments of the methodology described herein. The computer system 11 shown may be operational with numerous other general-purpose or special purpose computing system environments or configurations. Examples of well-known computing systems, environments, and/or configurations that may be suitable for use with the processing system shown in FIG. 10 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, supercomputers, quantum computing systems, hybrid systems including quantum computers and classical computers, and distributed cloud computing environments that include any of the above systems or devices, and the like. Classical computers among computer system 11 can execute classical computing processes by performing operations based on information encoded in bits. Quantum computers among computer system 11 can execute quantum computing processes by performing operations based on information encoded in qubits.

The computer system 11 may be described in the general context of computer system executable instructions, such as program modules, being executed by a computer system. Generally, program modules may include routines, programs, objects, components, logic, data structures, and so on that perform particular tasks or implement particular abstract data types. The computer system 11 may be practiced in distributed cloud computing environments where tasks are performed by remote processing devices that are linked through a communications network. In a distributed cloud computing environment, program modules may be located in both local and remote computer system storage media including memory storage devices.

The components of computer system 11 may include, but are not limited to, one or more processors or processing units 12, a system memory 16, a bus 14, storage system(s) 18, I/O interface(s) 20, network adapter(s) 22, network 24, devices 26, and display(s) 28. Bus 14 may couple various components of computer system 11. The processor 12 may include modules (e.g., programming modules) that performs the methods described herein. The modules among processor 12 may be programmed into the integrated circuits of the processor 12, or loaded from memory 16, storage device 18, or network 24 or combinations thereof. Processor 12 can be, for example, a microprocessor, a microcontroller, a processor core, a multicore processor, central processing unit (CPU) of computing devices such as a classical computer and/or quantum computers, and/or other types of computer processing element.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Universal Serial Bus (USB), Video Electronics Standards Association (VESA) local bus, and Peripheral Component Interconnects (PCI) bus.

Computer system 11 may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. Computer system may further include other removable/non-removable, volatile/non-volatile computer system storage media. By way of example, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

Computer system 11 may also communicate with one or more external devices 26 such as a keyboard, a pointing device, a display 28, network card, modem, etc. that enable a user to interact with computer system and/or that enable computer system 11 to communicate with one or more other computing devices. Devices 26 can be connected to components among computer system 11 via bus 14 and/or input/output (I/O) interfaces 20.

Computer system 11 can communicate with one or more networks 24 such as a local area network (LAN), a general wide area network (WAN), and/or a public network (e.g., the Internet) via network adapter 22 and/or I/O interfaces 20. Computer system 11 can communicate with networks 24 through wired connections (e.g., wires or cables connected to bus 14) or wireless connections (e.g., through network cards among I/O devices 20 and/or network adapter 22). Network adapter 22 can communicate with the other components of computer system 11 via bus 14. It should be understood that although not shown, other hardware and/or software components could be used in conjunction with computer system 11. Examples include, but are not limited to: field-programmable gate array (FPGA), system on chip (SoC), microcode, device drivers, redundant processing units, external disk drive arrays, RAID systems, tape drives, and data archival storage systems, etc.

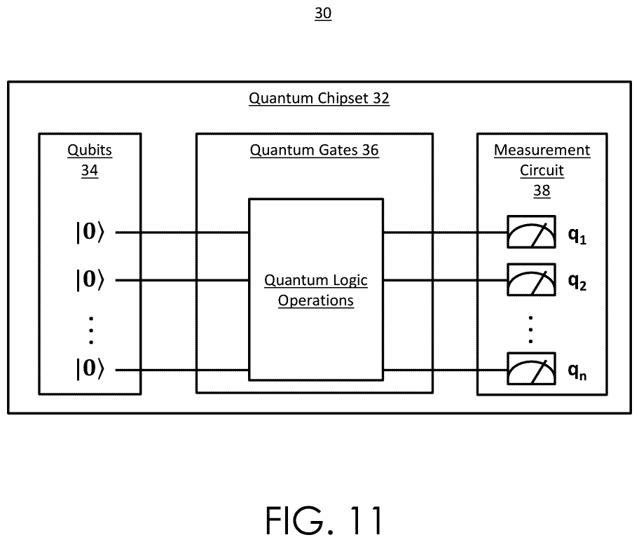

FIG. 11 illustrates a schematic of an example quantum computing system 30 that may implement one or more quantum circuits for simulating a boundary operator in one embodiment of the present disclosure. Quantum computing system 30 can be implemented by a quantum computer among processor 12 shown in FIG. 10, or coupled to network 24 shown in FIG. 10. For example, quantum computing system 30 can include a quantum processor shown in FIG. 1 at 102. Quantum computing system 30 can include a quantum chipset 32. Quantum chipset 32 can include one or more components configured to operate on a plurality of qubits 34. For example, a quantum circuit shown at 104 in FIG. 1 can include components of the quantum chipset 32. In an aspect, qubits 34 can be arranged in a two-dimensional or three-dimensional array, such as being arranged in a lattice structure. A two-dimensional qubit array can be formed on a surface of a two-dimensional wafer, and the qubits 34 can be arranged in a two-dimensional lattice structure and configured to communicate with one another. A three-dimensional device array can be formed by a stack of two-dimensional wafers, and qubits 34 can be arranged in a three-dimensional lattice structure and configured to communicate with one another via connections between the two-dimensional wafers.

Quantum chipset 32 can be a quantum computing core surrounded by an infrastructure to shield quantum chipset 32 from sources of electromagnetic noise, mechanical vibration, heat, and other sources of noise, which tend to degrade performance. Magnetic shielding can be used to shield the system components from stray magnetic fields, optical shielding can be used to shield the system components from optical noise, thermal shielding and cryogenic equipment can be used to maintain the system components at controlled temperature, etc. For example, an infrastructure that can surround quantum chipset 32 can be a refrigerator that can cool the quantum chipset to an operating temperature of quantum chipset 32.

In the figure, the plurality of qubits can be denoted as q1, q2 . . . , qn. Quantum chipset 32 can operate by performing quantum logic operations (e.g., using quantum gates 36) on qubits. Quantum gates 36 can include one or more single-qubit gates and/or two-qubit gates. Quantum circuits can be formed based on quantum gates 36, and quantum chipset 32 can operate the quantum circuits to perform quantum logic operations on single qubits or conditional quantum logic operations on multiple qubits. Conditional quantum logic can be performed in a manner that entangles the qubits. Control signals can be received by quantum chipset 32, and quantum chipset 32 can use the received control signals to manipulate the quantum states of individual qubits and the joint states of multiple qubits.

Measurement interface 38 can include circuit components configured to measure a basis of qubits 34, where the basis is a measurement that will yield a classical bit result. Each measurements performed by measurement interface circuit 38 can be read out to a device (e.g., a classical computer) connected to quantum computing system 30. A plurality of measurement results provided by measurement circuit 38 can result in a probabilistic outcome.

FIG. 12 illustrates a block diagram of an example system 40 that can facilitate execution of a quantum algorithm. As shown, a classical computer 41 can be electronically integrated, via any suitable wired and/or wireless electronic connection, with a quantum system 44. The quantum system 44 can be any suitable set of components capable of performing quantum operations on a physical system. In the example embodiment depicted in FIG. 11, quantum system 44 can include controller 45 (e.g., a local classical controller), an interface 46 (e.g., a classical-quantum interface), and quantum hardware 47. In some embodiments, all or part of each of the controller 45, the interface 46, and quantum hardware 47 may be located in a cryogenic environment to aid in the performance of the quantum operations.

Controller 45 may be any combination of digital computing devices capable of performing a quantum computation, such as executing a quantum circuit, in combination with interface 46. Such digital computing devices may include digital processors and memory for storing and executing quantum commands using interface 46. Additionally, such digital computing devices may include devices having communication protocols for receiving such commands and sending results of the performed quantum computations to classical computer 41. Additionally, the digital computing devices may include communications interfaces with the interface 46. Controller 45 can be configured to receive classical instructions (e.g., from classical computer 41) and convert the classical instructions into drive signals. The drive signals can be used for driving or manipulating qubits and/or quantum gates and/or circuits among quantum hardware 47.

Interface 46 may be a combination of devices capable of receiving command signals from controller 45 and converting those signals into quantum operations for execution on the quantum hardware 47. Additionally, interface 46 may be capable of converting signals received from the quantum hardware 47 into digital signals capable of processing and transmitting by controller 45. Devices included in interface 46 may include, but are not limited to, digital-to-analog converters, analog-to-digital converters, waveform generators, attenuators, amplifiers, optical fibers, lasers, and filters.

Quantum hardware 47 may be any hardware capable of using quantum states to process information. Such hardware may include a collection of qubits, and mechanisms to couple/entangle such qubits, in order to process information using said quantum states. Such qubits may include, but are not limited to, charge qubits, flux qubits, phase qubits, spin qubits, and trapped ion qubits.

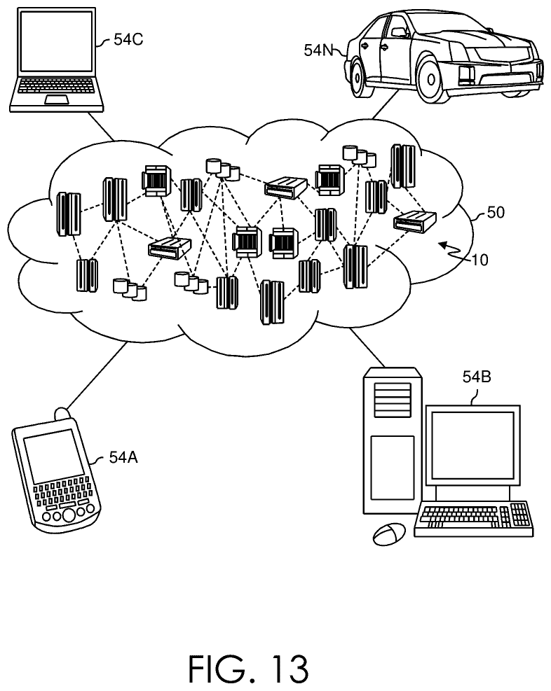

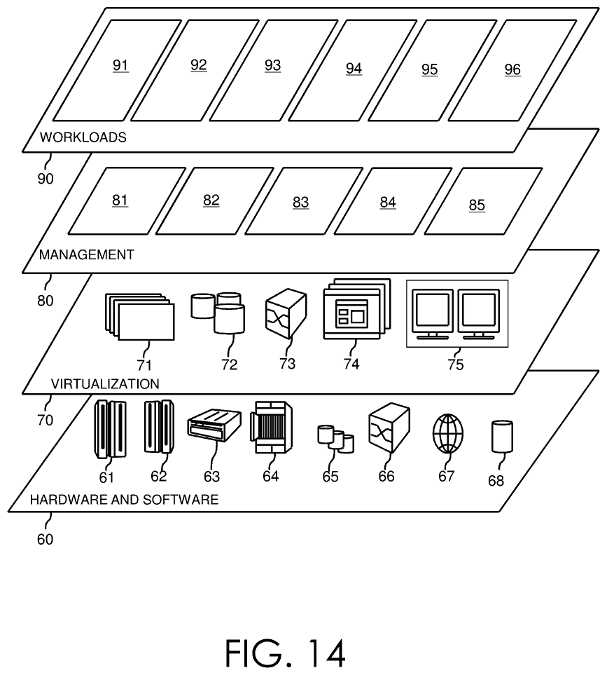

The classical computer 41 can be any suitable combination of computer-executable hardware and/or computer-executable software capable of executing a preparation module 42 to perform quantum computations with data contained in a data store 43 as part of building and implementing a machine learning protocol. Data store 43 may be a repository for data to be analyzed using a quantum computing algorithm, as well as the results of such analysis. In an example system, classical computer 41 can be a laptop computer, a desktop computer, a vehicle-integrated computer, a smart mobile device, a tablet device, and/or any other suitable classical computing device. Additionally or alternatively, classical computer 41 may also operate as part of a cloud computing service model, such as Software as a Service (SaaS), Platform as a Service (PaaS), or Infrastructure as a Service (IaaS). Classical computer 102 may also be located in a cloud computing deployment model, such as a private cloud, community cloud, public cloud, or hybrid cloud. Aspects of this embodiment are described in more detail below with reference to FIG. 13 and FIG. 14.

Preparation module 42 may be a program or module capable of preparing classical data from data store 43 to be analyzed as part of the implementation of a quantum circuit. Preparation module 42 may be instantiated as part of a larger algorithm, such as a function call of an application programming interface (API) or by parsing a hybrid classical-quantum computation into aspects for quantum and classical calculation. Preparation module 42 may generate instructions for creating a quantum circuit, e.g., using quantum gates. In an embodiment, such instructions may be stored by controller 41, and may instantiate the execution of the components of interface 46 so that the quantum operations of the quantum gates may be executed on quantum hardware 47.

It is understood in advance that although this disclosure may include a description on cloud computing, implementation of the teachings recited herein are not limited to a cloud computing environment. Rather, embodiments of the present invention are capable of being implemented in conjunction with any other type of computing environment now known or later developed. Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

Referring now to FIG. 13, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 13 are intended to be illustrative only and that computing nodes 10 and cloud computing environment 50 can communicate with any type of computerized device over any type of network and/or network addressable connection (e.g., using a web browser).

Referring now to FIG. 14, a set of functional abstraction layers provided by cloud computing environment 50 (FIG. 13) is shown. It should be understood in advance that the components, layers, and functions shown in FIG. 14 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and boundary operator processing 96.

The flowchart and block diagrams in the Figures illustrate the architecture, functionality, and operation of possible implementations of systems, methods, and computer products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, run concurrently, substantially concurrently, in a partially or wholly temporally overlapping manner, or the blocks may sometimes be run in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in an embodiment” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus comprising:
a controller configured to generate command signals;
quantum hardware including at least a plurality of qubits; and
an interface connected to the controller and the quantum hardware, the interface being configured to control the quantum hardware based on the command signals to implement a quantum circuit configured to simulate a boundary operator that creates a mapping of boundaries of a given graph having at least nodes and edges, the quantum circuit having linear depth relative to number of nodes in the given graph.

2. The apparatus of claim 1, wherein number of quantum gates in the quantum circuit has a linear relationship with the number of vertices in the given graph.

3. The apparatus of claim 1, wherein the boundary operator is defined as a sum of fermionic creation and annihilation operators.

4. The apparatus of claim 3, wherein the quantum circuit includes a cascade of two-qubit rotations implemented via quantum gates.

5. The apparatus of claim 4, wherein the quantum gates implementing the two-qubit rotations include Pauli quantum gates.

6. The apparatus of claim 4, wherein the cascade of two-qubit rotations is configured in the quantum circuit based at least on a pairwise Pauli anticommuntation property.

7. The apparatus of claim 1, wherein the boundary operator is represented in terms of a sum of Pauli spin operators, and wherein fermionic creation and annihilation operators are mapped to the Pauli spin operators.

8. The apparatus of claim 7, wherein the quantum circuit includes quantum gates that directly map with quantum computing primitives composing tensor product form of the boundary operator.

9. The apparatus of claim 1, wherein the quantum circuit includes at least n qubit input registers, wherein n represents number of vertices in the given graph, wherein input to the quantum circuit includes a quantum state vector representing a superposition of all polytopes in the given graph.

10. The apparatus of claim 9, wherein the quantum circuit outputs quantum states of the n qubits representative of boundaries of the polytopes in the given graph.

11. The apparatus of claim 1, wherein the quantum circuit includes at least:
n input qubit registers;
an ancilla qubit register;
n−1 sets of first quantum gates configured to perform two qubit Pauli Xᵢ₋₁ and Yᵢ rotations applied to (i−1)-th and i-th qubits, where i=1 to n−1;
an X-gate configured to act on (n−1)-th qubit; and
a series of n−1 sets of second quantum gates configured to reverse the two qubit rotations performed by the n−1 sets of first quantum gates.

12. The apparatus of claim 1, wherein the quantum circuit includes at least:
n input qubit registers;
an ancilla qubit register; and
n sets of third quantum gates, wherein a set of third quantum gates is configured to perform tensor product of Pauli X matrix and i number of Pauli Z matrices, for qubit register i, where i=0 to n−1.

13. The apparatus of claim 1, wherein the given graph represents a simplicial complex, wherein polytopes formed by hyperedges of the graph represent simplices in the simplicial complex, wherein the boundary operator creates a mapping of simplices of all orders in the simplicial complex.

14. A method comprising:
generating, by a controller of a quantum system, command signals;
converting, by an interface of the quantum system, the command signals into quantum operations; and
based on the quantum operations, controlling, by the interface of the quantum system, quantum hardware of the quantum system to construct a quantum circuit including at least Pauli quantum gates, the quantum circuit configured to simulate a boundary operator that creates a mapping of boundaries of a given graph having at least nodes and edges, the quantum circuit having linear depth relative to number of nodes in the given graph.

15. The method of claim 14, wherein fermionic creation and annihilation operators are mapped to Pauli spin operators representing the boundary operator.

16. The method of claim 14, wherein the quantum circuit has been simplified by reducing number of Pauli quantum gates based on anticommutation property associated with Pauli spin operators representing the boundary operator.

17. The method of claim 14, wherein the quantum circuit operates on n qubits corresponding to n nodes in the given graph, and an ancillar qubit.

18. The method of claim 17, wherein the quantum circuit operates on two qubits of the n qubits and an ancilla bit at a time.

19. The method of claim 17, wherein connectivity in the quantum circuit occurs only between the ancilla qubit and one the n qubits at a time.

20. The method of claim 14, wherein the given graph represents a simplicial complex, wherein polytopes formed by hyperedges of the graph represent simplices in the simplicial complex, wherein the boundary operator maps simplices of all orders in the simplicial complex.

21. A system comprising:
a first computing device configured to process data encoded in binary bits;
a second computing device configured to be in communication with the first computing device, wherein the second computing device comprises at least:
a controller configured to generate command signals;
quantum hardware including at least a plurality of qubits; and
an interface connected to the controller and the quantum hardware, the interface being configured to control the quantum hardware based on the command signals to implement a quantum circuit configured to simulate a boundary operator that creates a mapping of boundaries of a given graph having at least nodes and edges, the quantum circuit having linear depth relative to number of the nodes in the given graph.

22. The system of claim 21, wherein number of quantum gates in the quantum circuit has a linear relationship with the number of the nodes in the given graph.

23. The system of claim 21, wherein the boundary operator is defined as a sum of fermionic creation and annihilation operators.

24. The system of claim 23, wherein the quantum circuit includes a cascade of two-qubit rotations implemented via quantum gates, wherein the quantum gates implementing the two-qubit rotations include Pauli quantum gates, wherein the cascade of two-qubit rotations is configured in the quantum circuit based at least on a pairwise Pauli anticommuntation property.

25. An apparatus comprising:
a controller configured to generate command signals;
quantum hardware including at least a plurality of qubits; and
an interface connected to the controller and the quantum hardware, the interface being configured to control the quantum hardware based on the command signals to implement a quantum circuit configured to simulate a boundary operator that creates a mapping of simplices of orders in a given simplicial complex, the quantum circuit having linear depth relative to number of vertices in the given simplicial complex, and number of quantum gates in the quantum circuit has a linear relationship with the number of vertices in the given simplicial complex.
